(19) United States
(12) Patent Application Publication
(10) Pub. No.: US 2025/0221261 A1
(43) Pub. Date: Jul. 3, 2025

(54) DISPLAY DEVICE, METHOD OF FABRICATING THE SAME AND HEAD MOUNT DISPLAY DEVICE INCLUDING THE SAME

(71) Applicant: Samsung Display Co., LTD., Yongin-si (KR)

(72) Inventor: Soo Yeon HAN, Yongin-si (KR)

(21) Appl. No.: 18/916,478

(22) Filed: Oct. 15, 2024

(30) Foreign Application Priority Data
Dec. 27, 2023 (KR) 10-2023-0193272

(51) Int. Cl. H10K 59/80; H10K 59/12

(52) U.S. Cl. CPC H10K 59/873; H10K 59/1201; H10K 59/879

(57) ABSTRACT

A display device including: a substrate including a display area and a non-display area around the display area, a plurality of transistors being located on the substrate; a light emitting element layer on the substrate and including a plurality of light emitting elements in the display area; an encapsulation layer on the light emitting element layer; a color filter layer on the encapsulation layer and including a plurality of color filters overlapping the light emitting elements, respectively; a lens array layer on the color filter layer and including a plurality of lenses in the display area; a sealing dam structure in the non-display area and including a plurality of sealing dams surrounding the display area; and a cover layer on the lens array layer and located in an area surrounded by the sealing dam structure, the sealing dams including a first sealing dam and a second sealing dam.

### CROSS-REFERENCE TO RELATED APPLICATION

The present application claims priority to and the benefit of Korean Patent Application No. 10-2023-0193272, filed on Dec. 27, 2023, in the Korean Intellectual Property Office, the entire disclosure of which is incorporated by reference herein.

### BACKGROUND

### 1. Field

One or more embodiments of the present disclosure relate to a display device, a method of fabricating the same, and a head mounted display device including the same.

### 2. Description of the Related Art

A head mounted display (HMD) device is an image display device that is worn on a user's head in the form of glasses or a helmet and forms a focus at a distance close to user's eyes in front of the user's eyes. The head mounted display device may implement virtual reality (VR) or augmented reality (AR).

The head mounted display device magnifies and displays an image displayed by a small display device using a plurality of lenses. Therefore, a display device applied to the head mounted display device needs to provide a high-resolution image, for example, an image having a resolution of 3000 pixels per inch (PPI) or more. To this end, an organic light emitting diode on silicon (OLEDoS), which is a small organic light emitting display device having a high resolution, has been used as the display device applied to the head mounted display device. The OLEDOS is a device that displays an image by disposing organic light emitting diodes (OLEDs) on a semiconductor wafer substrate on which complementary metal oxide semiconductors (CMOSs) are disposed.

### SUMMARY

Aspects and features of embodiments of the present disclosure provide a display device including a cover layer including a resin and having a smooth upper surface without a separate hard cover member and including a plurality of sealing dams to improve quality of the cover layer, and a method of fabricating the same.

Aspects and features of embodiments of the present disclosure also provide a head mounted display device including the display device.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device including: a substrate including a display area and a non-display area around the display area, a plurality of transistors being located on the substrate; a light emitting element layer on the substrate and including a plurality of light emitting elements in the display area; an encapsulation layer on the light emitting element layer; a color filter layer on the encapsulation layer and including a plurality of color filters overlapping the light emitting elements, respectively; a lens array layer on the color filter layer and including a plurality of lenses in the display area; a sealing dam structure in the non-display area and including a plurality of sealing dams surrounding the display area; and a cover layer on the lens array layer and located in an area surrounded by the sealing dam structure, the plurality of sealing dams including a first sealing dam adjacent to the display area and a second sealing dam around the first sealing dam, and at least a portion of the cover layer being between the first sealing dam and the second sealing dam.

According to one or more embodiments, the sealing dam structure further includes a third sealing dam around the second sealing dam, and the cover layer does not go beyond the third sealing dam.

According to one or more embodiments, a height of the first sealing dam is smaller than heights of the second sealing dam and the third sealing dam, and wherein the heights of the second sealing dam and the third sealing dam are a same.

According to one or more embodiments, the cover layer covers the first sealing dam, and wherein the cover layer is not located between the second sealing dam and the third sealing dam.

According to one or more embodiments, a maximum thickness of the cover layer is the same as the heights of the second sealing dam and the third sealing dam.

According to one or more embodiments, heights of the first sealing dam, the second sealing dam, and the third sealing dam are the same, and wherein at least a portion of the cover layer is located between the second sealing dam and the third sealing dam.

According to one or more embodiments, the first sealing dam, the second sealing dam, and the third sealing dam include a same material.

According to one or more embodiments, the first sealing dam and the third sealing dam include a same material, and wherein the second sealing dam includes a different material from the first sealing dam and the third sealing dam.

According to one or more embodiments, the sealing dam structure further includes a base sealing dam below the first sealing dam and the second sealing dam, and wherein a thickness of the base sealing dam is greater than a thickness of each of the first sealing dam and the second sealing dam.

According to one or more embodiments, the first sealing dam and the second sealing dam include a same material, and wherein the base sealing dam includes a different material from the first sealing dam and the second sealing dam.

According to one or more embodiments, a width of each of the first sealing dam and the second sealing dam is in a range of 500 μm to 600 μm.

According to one or more embodiments, the first sealing dam and the second sealing dam include a polymer resin, and wherein the polymer resin has a viscosity in a range of 50,000 cP to 300,000 cP and has a thixotropic index in a range of 4 to 6.

According to one or more embodiments, the display device of further including a plurality of pads disposed in the non-display area of the substrate, wherein the sealing dam structure does not surround the pads, and the cover layer does not overlap the pads.

According to one or more embodiments, a method of fabricating a display device, including: preparing a substrate on which a plurality of transistors is located and in which a plurality of unit areas are defined and forming a light emitting element layer, an encapsulation layer, a color filter layer, and a lens array layer in each of the unit areas of the substrate, the light emitting element layer including a plurality of light emitting elements, the encapsulation layer being on the light emitting element layer, the color filter layer being on the encapsulation layer, and the lens array layer being on the color filter layer; forming a plurality of sealing dam resins around a display area where the light emitting element layer is located and applying a resin layer onto the lens array layer in an area surrounded by the sealing dam resins; planarizing an upper surface of the resin layer by disposing a release film on the resin layer and the sealing dam resins; and forming a cover layer and a plurality of sealing dams by curing the resin layer and the sealing dam resins and forming a plurality of display panels by dividing the substrate for each of the unit areas, the cover layer around the light emitting element layer, the encapsulation layer, the color filter layer, and the lens array layer, and the plurality of sealing dams around the display area, at least a portion of the cover layer being between the plurality of sealing dams.

According to one or more embodiments, the plurality of sealing dam resins include a first sealing dam resin, a second sealing dam resin, and a third sealing dam resin, and wherein the first sealing dam resin has a height smaller than heights of the second sealing dam resin and the third sealing dam resin, and is most adjacent to the display area from among the plurality of sealing dam resins.

According to one or more embodiments, in the planarizing of the upper surface of the resin layer, the heights of the second sealing dam resin and the third sealing dam resin become the same.

According to one or more embodiments, heights of the plurality of sealing dam resins are the same, and wherein at least a portion of the cover layer is between an outermost sealing dam of the plurality of sealing dams and a sealing dam located inside the outermost sealing dam.

According to one or more embodiments, the plurality of sealing dam resins include a first sealing dam resin, a second sealing dam resin around the first sealing dam resin and having a smaller height than the first sealing dam resin, and a third sealing dam resin around the second sealing dam resin and having a same height as the first sealing dam resin, and wherein each of the first sealing dam resin and the third sealing dam resin includes an uncured-type polymer resin, and the second sealing dam resin includes a fast cured-type polymer resin.

According to one or more embodiments, the plurality of sealing dam resins include a first sealing dam resin, a second sealing dam resin around the first sealing dam resin, and a third sealing dam resin located below the first sealing dam resin and the second sealing dam resin, and wherein a width of the third sealing dam resin is greater than a width of each of the first sealing dam resin and the second sealing dam resin.

According to one or more embodiments, a head mounted display device including: a frame corresponding to left and right eyes of a user; a plurality of display devices in the frame; and eyepieces on the plurality of display devices, respectively, wherein the display device includes: a substrate including a display area and a non-display area around the display area, a plurality of transistors being on the substrate; a light emitting element layer on the substrate and including a plurality of light emitting elements in the display area; an encapsulation layer on the light emitting element layer; a color filter layer on the encapsulation layer and including a plurality of color filters overlapping the light emitting elements, respectively; a lens array layer on the color filter layer and including a plurality of lenses in the display area; a sealing dam structure in the non-display area and including a plurality of sealing dams around the display area; and a cover layer on the lens array layer and located in an area surrounded by the sealing dam structure, the plurality of sealing dams including an innermost sealing dam adjacent to the display area, an outermost sealing dam around the innermost sealing dam, and at least one intermediate dam between the innermost sealing dam and the outermost sealing dam, and at least a portion of the cover layer being between the outermost sealing dam and the innermost sealing dam, and not being outside the outermost sealing dam.

According to the aforementioned and other embodiments of the present disclosure, a cover layer may be formed by flatly forming an upper surface and side surfaces of a resin layer applied onto a light emitting element layer on a wafer substrate and curing the resin layer. Accordingly, the cover layer may have a smooth upper surface and protecting a display panel without a separate hard cover member.

In addition, according to the aforementioned and other embodiments of the present disclosure, a plurality of sealing dams, such that the applied resin layer may be formed to completely fill an area surrounded by the sealing dams without overflowing the area or generating an insufficient portion. Accordingly, the resin layer may be uniformly applied regardless of a position during fabricating processes of the display device, and quality of the cover layer may be improved.

### BRIEF DESCRIPTION OF THE DRAWINGS

The above and other embodiments and features of the present disclosure will become more apparent by describing embodiments thereof with reference to the attached drawings, in which:

FIG. 1 is an exploded perspective view of a display device according to one or more embodiments;

FIG. 2 is a block diagram illustrating the display device according to one or more embodiments;

FIG. 3 is an equivalent circuit diagram of a sub-pixel according to one or more embodiments;

FIG. 4 is a diagram illustrating a display panel according to one or more embodiments;

FIG. 5 is a diagram illustrating an arrangement of a sealing dam structure and a cover layer disposed in the display panel according to one or more embodiments;

FIG. 6 is a plan view illustrating first electrodes and emission areas of a plurality of sub-pixels and a pixel defining film that are disposed in a display area of FIG. 4;

FIG. 7 is a plan view illustrating first electrodes and emission areas of a plurality of sub-pixels and a pixel defining film according to one or more embodiments;

FIG. 8 is a schematic cross-sectional view taken along the line A-A′ of FIG. 6;

FIG. 9 is an enlarged view of an area X of FIG. 4;

FIG. 10 is a schematic cross-sectional view taken along the line B-B′ of FIG. 9;

FIG. 11 is an enlarged view of an area Y of FIG. 4;

FIG. 12 is a schematic cross-sectional view taken along the line C-C′ of FIG. 11;

FIG. 13 is a schematic cross-sectional view of the display panel according to one or more embodiments taken along a second direction;

FIG. 14 is a cross-sectional view illustrating a sealing dam structure of the display device according to one or more embodiments in more detail;

FIGS. 15-25 are views sequentially illustrating fabricating processes of the display device according to one or more embodiments;

FIG. 26 is a schematic cross-sectional view of a display panel of a display device according to one or more embodiments taken along the second direction;

FIG. 27 is a cross-sectional view illustrating a sealing dam structure of the display device of FIG. 26 in more detail;

FIGS. 28 and 29 are cross-sectional views illustrating some of fabricating processes of the display device of FIG. 26;

FIG. 30 is a cross-sectional view illustrating a sealing dam structure of a display device according to still another embodiment in more detail;

FIGS. 31 and 32 are cross-sectional views illustrating some of fabricating processes of the display device including the sealing dam structure of FIG. 30;

FIG. 33 is a cross-sectional view illustrating a sealing dam structure of a display device according to one or more embodiments in more detail;

FIGS. 34 and 35 are cross-sectional views illustrating some of fabricating processes of the display device including the sealing dam structure of FIG. 33;

FIG. 36 is a perspective view illustrating a head mounted display device according to one or more embodiments;

FIG. 37 is an exploded perspective view illustrating an example of the head mounted display device of FIG. 36; and

FIG. 38 is a perspective view illustrating a head mounted display device according to one or more embodiments.

### DETAILED DESCRIPTION

Aspects and features of embodiments of the present disclosure and methods of accomplishing the same may be understood more readily by reference to the detailed description of embodiments and the accompanying drawings.

Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

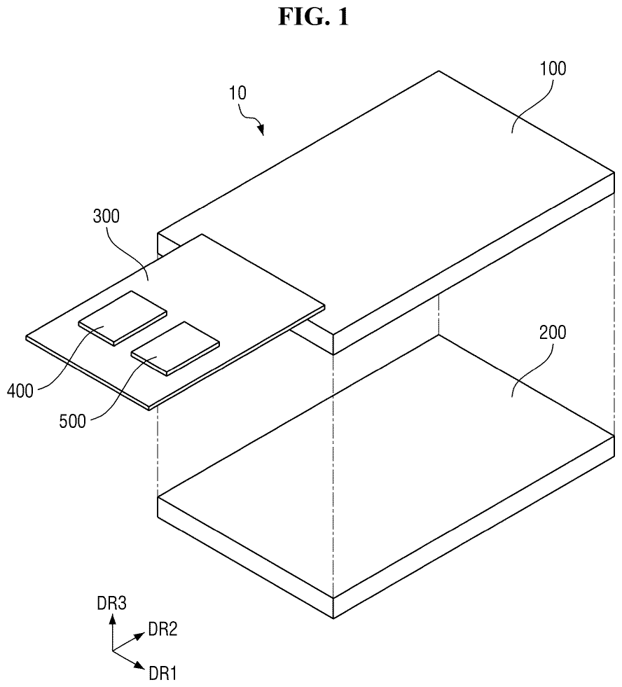

FIG. 1 is an exploded perspective view of a display device according to one or more embodiments.

Referring to FIG. 1, a display device 10 according to one or more embodiments is a device that displays a moving image and/or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 may be applied as a display unit of televisions, laptop computers, monitors, billboards, and/or the Internet of Things (IOTs). Alternatively, the display device 10 may be applied to smart watches, watch phones, and/or head mounted display (HMD) devices for realizing virtual reality and augmented reality.

The display device 10 according to one or more embodiments includes a display panel 100, a heat dissipation layer 200, a circuit board 300, a timing controller 400, and a power supply unit 500.

The display panel 100 may have a shape similar to a rectangular shape in a plan view. For example, the display panel 100 may have a shape similar to a rectangular shape, in a plan view, having short sides in a first direction DR1 and long sides in a second direction DR2 crossing the first direction DR1. In the display panel 100, a corner where the short side in the first direction DR1 and the long side in the second direction DR2 meet may be rounded with a suitable curvature (e.g., a predetermined curvature) or right-angled. A shape of the display panel 100 in a plan view is not limited to the rectangular shape, and may be a shape similar to other polygonal shapes, a circular shape, and/or an elliptical shape. A shape of the display device 10 in a plan view may follow the shape of the display panel 100 in a plan view, but is not limited thereto.

The heat dissipation layer 200 may overlap the display panel 100 in a third direction DR3, which is a thickness direction of the display panel 100. The heat dissipation layer 200 may be disposed on one surface, for example, a rear surface, of the display panel 100. The heat dissipation layer 200 serves to dissipate heat generated from the display panel 100. The heat dissipation layer 200 may include a conductive layer made of graphite, silver (Ag), copper (Cu), and/or aluminum (Al) having high thermal conductivity.

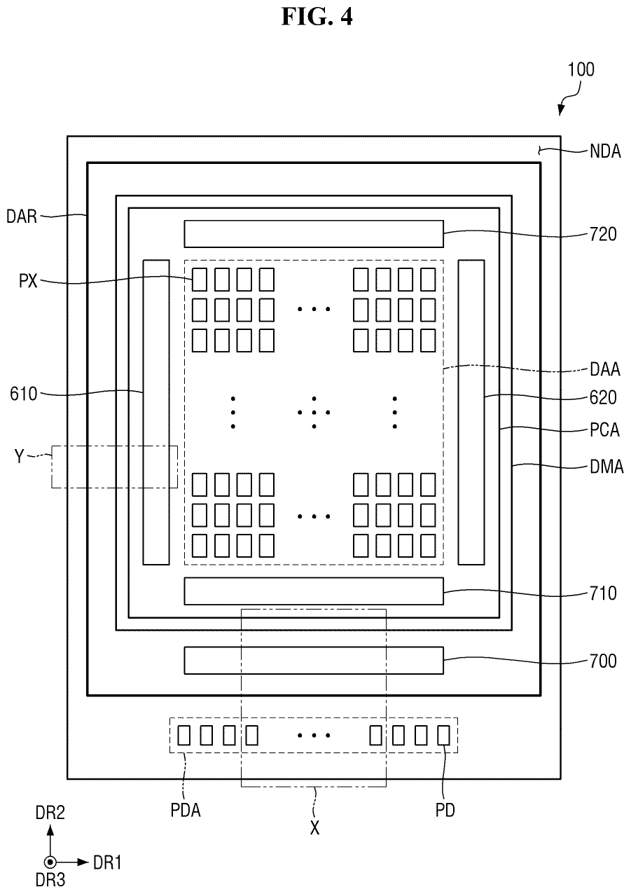

The circuit board 300 may be electrically connected to a plurality of pads PD (see FIG. 4) of a pad portion PDA (see FIG. 4) of the display panel 100 using a conductive adhesive member such as an anisotropic conductive film. The circuit board 300 may be a flexible printed circuit board (FPCB) or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. One end of the circuit board 300 may be an end opposite to the other end of the circuit board 300 connected to the plurality of pads PD (see FIG. 4) of the pad portion PDA (see FIG. 4) of the display panel 100 using the conductive adhesive member.

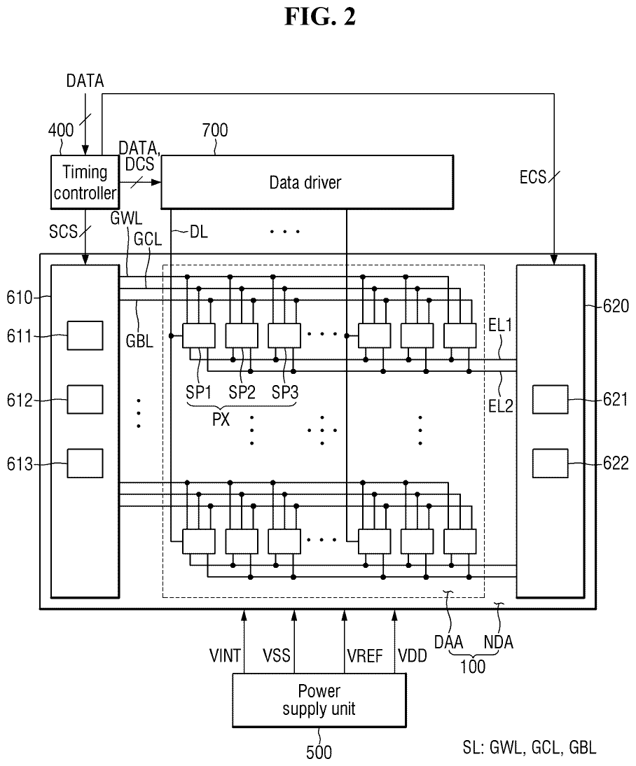

The timing controller 400 may receive digital video data and timing signals from the outside. The timing controller 400 may generate a scan timing control signal SCS (see FIG. 2), an emission timing control signal ECS (see FIG. 2), and a data timing control signal DCS (see FIG. 2) for controlling the display panel 100 according to the timing signals. The timing controller 400 may output the scan timing control signal SCS to a scan driver 610 (see FIG. 2) and output the emission timing control signal ECS to an emission driver 620 (see FIG. 2). The timing controller 400 may output the digital video data DATA and the data timing control signal DCS to a data driver 700 (see FIG. 2).

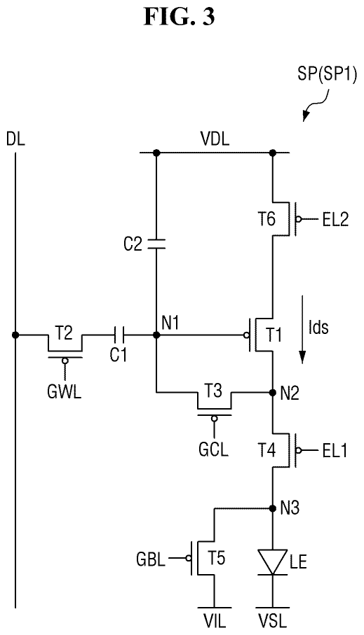

The power supply unit 500 may generate a plurality of panel driving voltages according to an external source voltage. For example, the power supply unit 500 may generate a first driving voltage VSS (see FIG. 2), a second driving voltage VDD (see FIG. 2), and a third driving voltage VINT (see FIG. 2) and supply the first driving voltage VSS, the second driving voltage VDD, and the third driving voltage VINT to the display panel 100. The first driving voltage VSS, the second driving voltage VDD, and the third driving voltage VINT will be described later with reference to FIG. 3. In one or more embodiments, the power supply unit 500 may also generate a reference voltage VREF and supply the reference voltage VREF to the display panel 100.

Each of the timing controller 400 and the power supply unit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

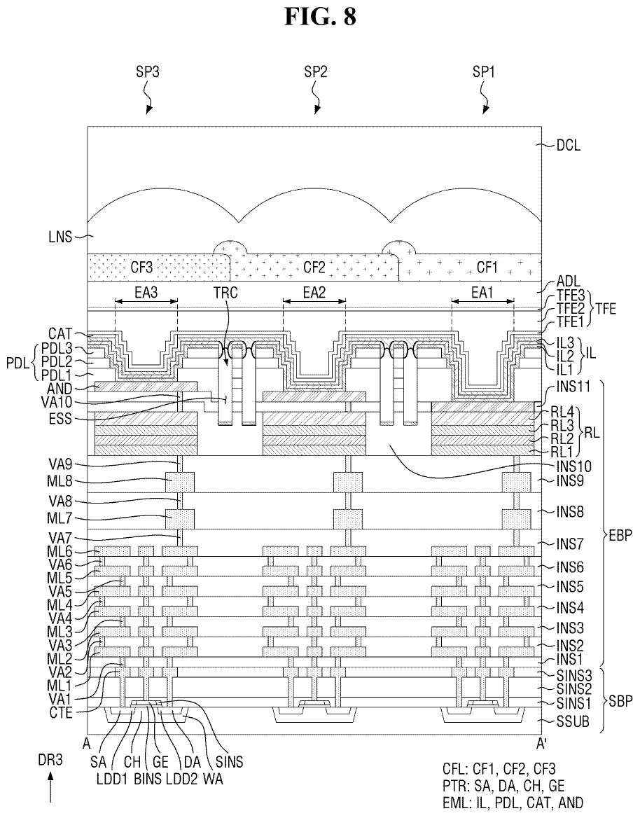

Alternatively, each of the timing controller 400 and the power supply unit 500 may be disposed in a non-display area NDA (see FIG. 2) of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and formed on a semiconductor substrate SSUB (see FIG. 8). For example, the plurality of timing transistors and the plurality of power transistors may be formed as complementary metal oxide semiconductors (CMOSs). Each of the timing controller 400 and the power supply unit 500 may be disposed between the data driver 700 and the pad portion PDA (see FIG. 4).

FIG. 2 is a block diagram illustrating the display device according to one or more embodiments.

Referring to FIG. 2, the display panel 100 may include a display area DAA and a non-display area NDA disposed around the display area DAA along an edge or a periphery of the display area DAA. The display area DAA may emit light or display an image by having a plurality of pixels PX disposed therein, and the non-display area NDA may not emit light or display an image.

The display panel 100 may include the plurality of pixels PX, a plurality of scan lines SL, a plurality of emission control lines EL, and a plurality of data lines DL disposed in the display area DAA.

The plurality of pixels PX may be arranged in the first direction DR1 and the second direction DR2. The plurality of pixels PX may be arranged in a matrix form in the display area DAA. The plurality of scan lines SL and the plurality of emission control lines EL may extend in the first direction DR1 and may be disposed to be spaced (or spaced apart) from each other in the second direction DR2. The plurality of data lines DL may extend in the second direction DR2 and may be disposed to be spaced (or spaced apart) from each other in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

Each of the plurality of pixels PX may include a plurality of sub-pixels SP1, SP2, and SP3. The plurality of sub-pixels SP1, SP2, and SP3 may include a plurality of pixel transistors as illustrated in FIG. 3. The plurality of pixel transistors may be formed by a semiconductor process and disposed on a semiconductor substrate SSUB (see FIG. 8). For example, the plurality of pixel transistors may be formed as CMOSs.

Each of the plurality of sub-pixels SP1, SP2, and SP3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of sub-pixels SP1, SP2, and SP3 may receive a data voltage of the data line DL according to a write scan signal of the write scan line GWL, and allow a light emitting element to emit light according to the data voltage.

The display panel 100 may include the scan driver 610, the emission driver 620, and the data driver 700 disposed in the non-display area NDA.

The scan driver 610 includes a plurality of scan transistors, and the emission driver 620 includes a plurality of light emitting transistors. The plurality of scan transistors and the plurality of light emitting transistors may be formed by a semiconductor process and formed on a semiconductor substrate SSUB (see FIG. 8). For example, the plurality of scan transistors and the plurality of light emitting transistors may be formed as CMOSs. It has been illustrated in FIG. 2 that the scan driver 610 is disposed on the left side of the display area DAA and the emission driver 620 is disposed on the right side of the display area DAA, but the present disclosure is not limited thereto. For example, the scan drivers 610 and the emission drivers 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive the scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driver 621 and a second emission control driver 622. Each of the first emission control driver 621 and the second emission control driver 622 may receive the emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and formed on a semiconductor substrate SSUB (see FIG. 8). For example, the plurality of data transistors may be formed as CMOSs.

The data driver 700 may receive the digital video data DATA and the data timing control signal DCS from the timing controller 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

FIG. 3 is an equivalent circuit diagram of a sub-pixel according to one or more embodiments.

Referring to FIG. 3, a sub-pixel SP (SP1) may be connected to a write scan line GWL, a control scan line GCL, a bias scan line GBL, a first emission control line EL1, a second emission control line EL2, and a data line DL. In addition, the sub-pixel SP may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage or the third driving voltage VINT is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The sub-pixel SP includes a plurality of transistors T1 to T6, a light emitting element LE, a first capacitor C1, and a second capacitor C2.

The light emitting element LE emits light according to a driving current Ids flowing through a channel of a first transistor T1. An amount of light emitted from the light emitting element LE may be proportional to the driving current Ids. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but is not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor controlling a source-drain current Ids (hereinafter referred to as a “driving current”) flowing between a source electrode and a drain electrode of the first transistor T1 according to a voltage applied to a gate electrode of the first transistor T1 thereof. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor C1 and the data line DL. The second transistor T2 is turned on by a write scan signal of the write scan line GWL to connect one electrode of the first capacitor C1 to the data line DL. For this reason, a data voltage of the data line DL may be applied to one electrode of the first capacitor C1. The second transistor T2 includes a gate electrode connected to the write scan line GWL, a source electrode connected to the data line DL, and a drain electrode connected to one electrode of the first capacitor C1.

A third transistor T3 may be disposed between the first node N1 and the second node N2. The third transistor T3 is turned on by a control scan signal of the control scan line GCL to connect the first node N1 to the second node N2. For this reason, the gate electrode and the drain electrode of the first transistor T1 are connected to each other, and thus, the first transistor T1 may operate like a diode (e.g., the first transistor T1 may be diode-connected). The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 is turned on by a bias scan signal of the bias scan line GBL to connect the third node N3 to the third driving voltage line VIL. For this reason, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 (or the first node N1) and the other electrode connected to the second driving voltage line VDL.

The first node N1 is a contact point between the gate electrode of the first transistor T1, the drain electrode of the third transistor T3, the other electrode of the first capacitor C1, and one electrode of the second capacitor C2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but is not limited thereto. Each of the first to sixth transistors T1 to T6 may be an N-type MOSFET. Alternatively, some of the first to sixth transistors T1 to T6 may be P-type MOSFETs, and the others of the first to sixth transistors T1 to T6 may be N-type MOSFETs.

It has been illustrated in FIG. 3 that the sub-pixel SP includes six transistors T1 to T6 and two capacitors C1 and C2, but it is to be noted that an equivalent circuit diagram of the sub-pixel SP is not limited to that illustrated in FIG. 3. For example, the numbers of transistors and capacitors of the sub-pixel SP are not limited to those illustrated in FIG. 3.

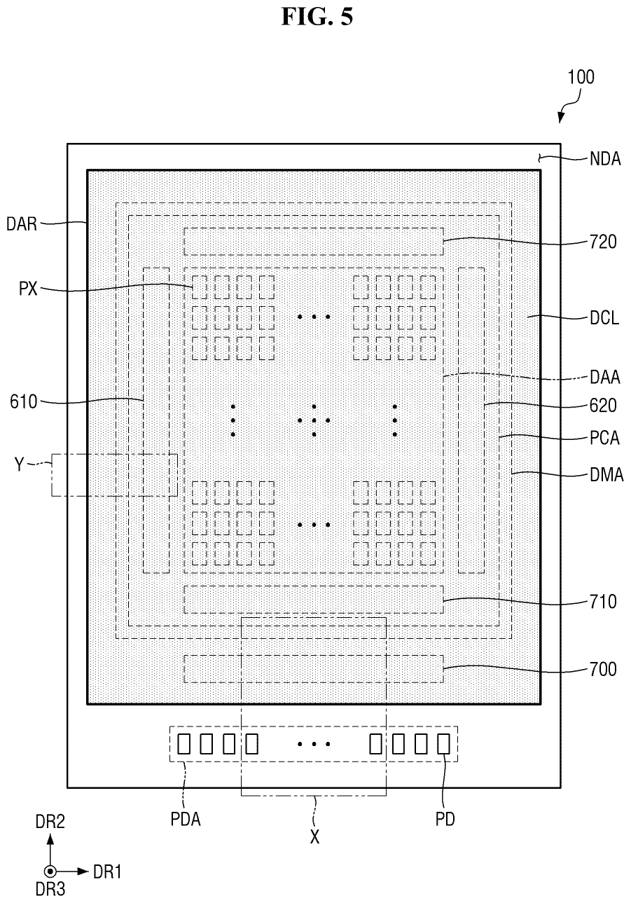

FIG. 4 is a diagram illustrating a display panel according to one or more embodiments. FIG. 5 is a diagram illustrating an arrangement of a sealing dam structure and a cover layer disposed in the display panel according to one or more embodiments. FIG. 5 illustrates an arrangement of a sealing dam structure DAR and a cover layer DCL in the display panel 100 of FIG. 4.

Referring to FIGS. 4 and 5, the display panel 100 according to one or more embodiments may include a plurality of pixels PX arranged in a matrix form in the display area DAA. For example, the plurality of pixels PX may be arranged along rows and columns of a matrix in the display area DAA. The display panel 100 may include a scan driver 610, an emission driver 620, a data driver 700, a first distribution circuit 710, a second distribution circuit 720, a pad portion PDA, a power connection portion PCA, a dam DMA, and the sealing dam structure DAR that are disposed in the non-display area NDA. In addition, in one or more embodiments, the display panel 100 may further include an electrostatic protection portion, a moisture permeation prevention portion, and a crack prevention portion that are disposed between the dam DMA and the sealing dam structure DAR.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan drivers 610 and the emission drivers 620 may be disposed on both the first and second sides of the display area DAA.

The pad portion PDA may include a plurality of pads PD connected to pads or bumps of the circuit board 300 through a conductive adhesive member. The pad portion PDA may be disposed on a third side of the display area DAA. For example, the pad portion PDA may be disposed on one side of the display area DAA in the second direction DR2. The pad portion PDA may be disposed on the lower side of the display area DAA. The pad portion PDA may be disposed outside the data driver 700 in the second direction DR2. That is, the pad portion PDA may be disposed closer to an edge of the display panel 100 than the data driver 700 is.

In one or more embodiments, the display panel 100 may further include inspection pads for inspecting whether or not the display panel 100 operates normally. The inspection pads may be connected to a jig or a probe pin or connected to a circuit board for inspection in an inspection process. The circuit board for inspection may be a printed circuit board (PCB) made of a rigid material or a flexible printed circuit board (FPCB) made of a flexible material.

The first distribution circuit 710 distributes data voltages applied through the pad portion PDA to the plurality of data lines DL. For example, the first distribution circuit 710 may distribute data voltages applied through one pad PD of the pad portion PDA to P data lines DL (P is a positive integer of 2 or more), and for this reason, the number of pads PD may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the pad portion PDA to the scan driver 610, the emission driver 620, and the data lines DL. The second distribution circuit 720 may be a component for inspecting an operation of each of the pixels PX of the display area DAA. The second distribution circuit 720 may be disposed on a fourth side of the display area DAA of the display panel 100. For example, the second distribution circuit 720 may be disposed on the other side of the display area DAA in the second direction DR2. That is, the second distribution circuit 720 may be disposed on the upper side of the display area DAA. However, the second distribution circuit 720 may also be omitted.

The power connection portion PCA refers to an area where the second electrode of the light emitting element LE (see FIG. 3) and a power connection electrode to which the first driving voltage VSS is applied are connected to each other in order to apply the first driving voltage VSS to the second electrode of the light emitting element LE (see FIG. 3).

The power connection portion PCA may be disposed to be around (e.g., to surround) the display area DAA. In addition, the power connection portion PCA may be disposed outside the scan driver 610, the emission driver 620, the first distribution circuit 710, and the second distribution circuit 720. For example, the power connection portion PCA may be disposed more adjacent to edges of the display panel 100 than the scan driver 610, the emission driver 620, the first distribution circuit 710, and the second distribution circuit 720 are. The power connection portion PCA may be disposed to be around (e.g., to surround) the scan driver 610, the emission driver 620, the first distribution circuit 710, and the second distribution circuit 720. However, the present disclosure is not limited thereto, and the power connection portion PCA may also overlap at least one of the scan driver 610, the emission driver 620, the first distribution circuit 710, and the second distribution circuit 720 in the third direction DR3.

The dam DMA may be a structure for preventing an organic encapsulation layer TFE2 of an encapsulation layer TFE (see FIG. 8) for encapsulating the light emitting elements LE (see FIG. 3) from overflowing into the pad portion PDA.

The dam DMA may be disposed to be around (e.g., to surround) the display area DAA. In addition, the dam DMA may be disposed outside the scan driver 610, the emission driver 620, the first distribution circuit 710, and the second distribution circuit 720. For example, the dam DMA may be disposed more adjacent to the edges of the display panel 100 than the scan driver 610, the emission driver 620, the first distribution circuit 710, and the second distribution circuit 720 are. The dam DMA may be disposed to be around (e.g., to surround) the scan driver 610, the emission driver 620, the first distribution circuit 710, and the second distribution circuit 720. However, the present disclosure is not limited thereto, and the dam DMA may also overlap at least one of the scan driver 610, the emission driver 620, the first distribution circuit 710, and the second distribution circuit 720 in the third direction DR3.

In addition, the dam DMA may be disposed outside the power connection portion PCA. For example, the dam DMA may be disposed more adjacent to the edges of the display panel 100 than the power connection portion PCA is. The dam DMA may be disposed to be around (e.g., to surround) the power connection portion PCA.

According to one or more embodiments, the display device 10 may include the sealing dam structure DAR and the cover layer DCL disposed in the display panel 100. The sealing dam structure DAR may be disposed outside the dam DMA so as to be around (e.g., to surround) the display area DAA and the dam DMA. The scan driver 610, the emission driver 620, the first distribution circuit 710, and the second distribution circuit 720 may be disposed in an area surrounded by the sealing dam structure DAR. In addition, the power connection portion PCA, and inspection pads, an electrostatic protection portion, a moisture permeation prevention portion, and a crack prevention portion may be disposed in the area surrounded by the sealing dam structure DAR.

The cover layer DCL may be disposed in the area surrounded by the sealing dam structure DAR. The cover layer DCL may be disposed to cover at least the pixels PX or a light emitting element layer EML (see FIG. 8) of the display area DAA. For example, the sealing dam structure DAR may be disposed at an outer portion of the dam DMA in the non-display area NDA, and the cover layer DCL may be disposed over the display area DAA and a portion of the non-display area NDA and disposed to overlap the plurality of pixels PX, the scan driver 610, the emission driver 620, the first distribution circuit 710, the second distribution circuit 720, the power connection portion PCA, and the dam DMA. The cover layer DCL is an uppermost layer of the display panel 100, and may protect components disposed in the display panel 100.

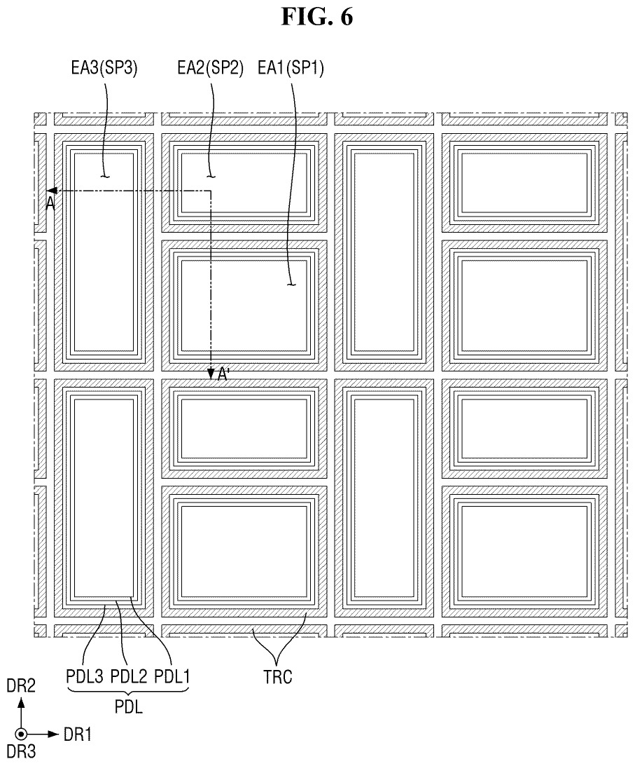

FIG. 6 is a plan view illustrating first electrodes and emission areas of a plurality of sub-pixels and a pixel defining film that are disposed in a display area of FIG. 4.

Referring to FIG. 6, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include a first emission area EA1, the second sub-pixel SP2 may include a second emission area EA2, and the third sub-pixel SP3 may include a third emission area EA3.

Each of the first emission area EA1, the second emission area EA2, and the third emission area EA3 may be an area defined by a pixel defining film PDL. For example, each of the first emission area EA1, the second emission area EA2, and the third emission area EA3 may be an area defined by a first pixel defining film PDL1.

A length of the third emission area EA3 in the first direction DR1 may be smaller than a length of the first emission area EA1 in the first direction DR1 and smaller than a length of the second emission area EA2 in the first direction DR1. The length of the first emission area EA1 in the first direction DR1 and the length of the second emission area EA2 in the first direction DR1 may be substantially the same as each other.

In each of the plurality of pixels PX, the first emission area EA1 and the second emission area EA2 may neighbor each other in the second direction DR2. In addition, the first emission area EA1 and the third emission area EA3 may neighbor each other in the first direction DR1. In addition, the second emission area EA2 and the third emission area EA3 may neighbor each other in the first direction DR1. An area of the first emission area EA1, an area of the second emission area EA2, and an area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm and 750 nm.

A first electrode AND of the light emitting element LE may have a rectangular shape in a plan view. The shape of the first electrode AND of the light emitting element LE in a plan view may be different in the first sub-pixel SP1, the second sub-pixel SP2, and the third sub-pixel SP3. For example, each of the first electrode AND of the first sub-pixel SP1 and the first electrode AND of the second sub-pixel SP2 may have a rectangular shape, in a plan view, having long sides in the first direction DR1 and short sides in the second direction DR2. The first electrode AND of the third sub-pixel SP3 may have a rectangular shape, in a plan view, having short sides in the first direction DR1 and long sides in the second direction DR2. A length of the first electrode AND of the third sub-pixel SP3 in the first direction DR1 may be smaller than a length of the first electrode AND of each of the first sub-pixel SP1 and the second sub-pixel SP2 in the first direction DR1. A length of the first electrode AND of the first sub-pixel SP1 in the second direction DR2 may be greater than a length of the first electrode AND of the second sub-pixel SP2 in the second direction DR2.

The first electrode AND of the light emitting element LE may be connected to a reflective electrode layer RL (see FIG. 8) through a tenth via VA10. The tenth via VA10 may overlap the first pixel defining film PDL1, a second pixel defining film PDL2, and a third pixel defining film PDL3 in the third direction DR3.

At least one trench TRC may be a structure for disconnecting at least one charge generation layer of a light emitting stack IL between the emission areas EA1, EA2, and EA3 neighboring each other. At least one trench TRC may be disposed between the first emission area EA1 and the second emission area EA2, between the first emission area EA1 and the third emission area EA3, and between the second emission area EA2 and the third emission area EA3. More specifically, at least one trench TRC may be disposed between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

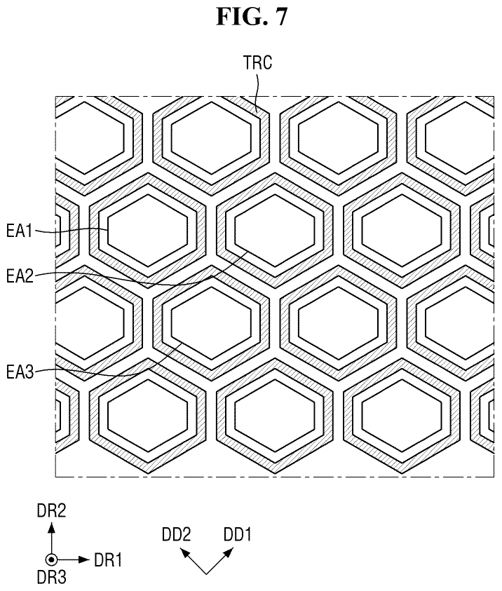

FIG. 7 is a plan view illustrating first electrodes and emission areas of a plurality of sub-pixels and a pixel defining film according to one or more embodiments.

The embodiment of FIG. 7 is substantially the same as an embodiment of FIG. 6 except for shapes of a first emission area EA1, a second emission area EA2, and a third emission area EA3 in a plan view, and a description overlapping the description of the embodiment of FIG. 6 is thus omitted.

Referring to FIG. 7, the first emission area EA1, the second emission area EA2, and the third emission area EA3 may be disposed in a hexagonal structure having a hexagonal shape in a plan view. In this case, the first emission area EA1 and the second emission area EA2 may neighbor each other in the first direction DR1, but the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

It has been illustrated in FIGS. 6 and 7 that each of the plurality of pixels PX includes three emission areas EA1, EA2, and EA3, but the present disclosure is not limited thereto. That is, each of the plurality of pixels PX may also include four emission areas.

In addition, an arrangement of the emission areas EA1, EA2, and EA3 of the plurality of pixels PX is not limited to those illustrated in FIGS. 6 and 7. For example, the emission areas of the plurality of pixels PX may be disposed in a stripe structure in which the emission areas are arranged along the first direction DR1, a PENTILE® structure in which the emission areas have a Diamond Pixel® arrangement form. PENTILE® and Diamond Pixel® are registered trademarks of Samsung Display Co., Ltd., Republic of Korea.

FIG. 8 is a schematic cross-sectional view taken along the line A-A′ of FIG. 6.

Referring to FIG. 8, the display panel 100 may include a semiconductor backplane SBP, a light emitting element backplane EBP, a light emitting element layer EML, an encapsulation layer TFE, an adhesive layer ADL, a color filter layer CFL, a lens array layer LNS, and a cover layer DCL. In one or more embodiments, the display panel 100 may further include a polarizing plate disposed on the cover layer DCL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with first-type impurities. A plurality of well regions WA may be disposed in an upper surface of the semiconductor substrate SSUB. The plurality of well regions WA may be regions doped with second-type impurities. The second-type impurities may be different from the first-type impurities described above. For example, when the first-type impurities are P-type impurities, the second-type impurities may be N-type impurities. Alternatively, when the first-type impurities are N-type impurities, the second-type impurities may be P-type impurities.

Each of the plurality of well regions WA includes a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be prevented or reduced.

A first semiconductor insulating film SINS1 may be disposed on the semiconductor substrate SSUB and the pixel transistor PTR. The first semiconductor insulating film SINS1 may be formed as a silicon carbonitride (SiCN) or silicon oxide (SiOₓ)-based inorganic film, but is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may be made of copper (Cu), aluminum (Al), tungsten (W), molybdenum (Mo), chromium (Cr), gold (Au), titanium (Ti), nickel (Ni), and/or neodymium (Nd), and/or alloys thereof. A third semiconductor insulating film SINS3 may be disposed on the second semiconductor insulating film SINS2. The third semiconductor insulating film SINS3 may also be disposed on side surfaces of each of portions of the plurality of contact terminals CTE disposed on the second semiconductor insulating film SINS2. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but is not limited thereto.

The semiconductor substrate SSUB may be replaced with a glass substrate and/or a polymer resin substrate such as a polyimide substrate. In this case, thin film transistors (TFTs) may be disposed on the glass substrate and/or the polymer resin substrate. The glass substrate may be a rigid substrate that is not bent, and the polymer resin substrate may be a flexible substrate that may be bent and/or curved.

The light emitting element backplane EBP includes first to eighth conductive layers ML1 to ML8, a reflective electrode layer RL, and a plurality of vias VA1 to VA10. In addition, the light emitting element backplane EBP includes a plurality of interlayer insulating films INS1 to INS11 disposed between the first to eighth conductive layers ML1 to ML8.

The first to eighth conductive layers ML1 to ML8 may constitute a circuit of the sub-pixel SP illustrated in FIG. 3 by connecting the plurality of contact terminals CTE exposed from the semiconductor backplane SBP to each other. That is, the first to sixth transistors T1 to T6 may be formed in the semiconductor backplane SBP, and the connection between the first to sixth transistors T1 to T6 and the formation of the first capacitor C1 and the second capacitor C2 may be performed through the first to eighth conductive layers ML1 to ML8. In addition, the connection between a drain region corresponding to the drain electrode of the fourth transistor T4, a source region corresponding to the source electrode of the fifth transistor T5, and the first electrode of the light emitting element LE may also be performed through the first to eighth conductive layers ML1 to ML8.

A first interlayer insulating film INS1 may be disposed on the semiconductor backplane SBP. Each of first vias VA1 may penetrate through the first interlayer insulating film INS1 to be connected to the contact terminal CTE exposed from the semiconductor backplane SBP. Each of the first conductive layers ML1 may be disposed on the first interlayer insulating film INS1 and may be connected to the first via VA1.

A second interlayer insulating film INS2 may be disposed on the first interlayer insulating film INS1 and the first conductive layers ML1. Each of second vias VA2 may penetrate through the second interlayer insulating film INS2 to be connected to the exposed first conductive layer ML1. Each of the second conductive layers ML2 may be disposed on the second interlayer insulating film INS2 and be connected to the second via VA2.

A third interlayer insulating film INS3 may be disposed on the second interlayer insulating film INS2 and the second conductive layers ML2. Each of third vias VA3 may penetrate through the third interlayer insulating film INS3 to be connected to the exposed second conductive layer ML2. Each of the third conductive layers ML3 may be disposed on the third interlayer insulating film INS3 and may be connected to the third via VA3.

A fourth interlayer insulating film INS4 may be disposed on the third interlayer insulating film INS3 and the third conductive layers ML3. Each of fourth vias VA4 may penetrate through the fourth interlayer insulating film INS4 to be connected to the exposed third conductive layer ML3. Each of the fourth conductive layers ML4 may be disposed on the fourth interlayer insulating film INS4 and may be connected to the fourth via VA4.

A fifth interlayer insulating film INS5 may be disposed on the fourth interlayer insulating film INS4 and the fourth conductive layers ML4. Each of fifth vias VA5 may penetrate through the fifth interlayer insulating film INS5 to be connected to the exposed fourth conductive layer ML4. Each of the fifth conductive layers ML5 may be disposed on the fifth interlayer insulating film INS5 and may be connected to the fifth via VA5.

A sixth interlayer insulating film INS6 may be disposed on the fifth interlayer insulating film INS5 and the fifth conductive layers ML5. Each of sixth vias VA6 may penetrate through the sixth interlayer insulating film INS6 to be connected to the exposed fifth conductive layer ML5. Each of the sixth conductive layers ML6 may be disposed on the sixth interlayer insulating film INS6 and may be connected to the sixth via VA6.

A seventh interlayer insulating film INS7 may be disposed on the sixth interlayer insulating film INS6 and the sixth conductive layers ML6. Each of seventh vias VA7 may penetrate through the seventh interlayer insulating film INS7 to be connected to the exposed sixth conductive layer ML6. Each of the seventh conductive layers ML7 may be disposed on the seventh interlayer insulating film INS7 and may be connected to the seventh via VA7.

An eighth interlayer insulating film INS8 may be disposed on the seventh interlayer insulating film INS7 and the seventh conductive layers ML7. Each of eighth vias VA8 may penetrate through the eighth interlayer insulating film INS8 to be connected to the exposed seventh conductive layer ML7. Each of the eighth conductive layers ML8 may be disposed on the eighth interlayer insulating film INS8 and may be connected to the eighth via VA8.

The first to eighth conductive layers ML1 to ML8 and the first to eighth vias VA1 to VA8 may be made of substantially the same material. Each of the first to eighth conductive layers ML1 to ML8 and the first to eighth vias VA1 to VA8 may be made of copper (Cu), aluminum (Al), tungsten (W), molybdenum (Mo), chromium (Cr), gold (Au), titanium (Ti), nickel (Ni), and/or neodymium (Nd), and/or alloys thereof. The first to eighth vias VA1 to VA8 may be made of substantially the same material. The first to eighth interlayer insulating films INS1 to INS8 may be formed as silicon oxide (SiOₓ)-based inorganic films, but are not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

A ninth interlayer insulating film INS9 may be disposed on the eighth interlayer insulating film INS8 and the eighth conductive layer ML8. The ninth interlayer insulating film INS9 may be formed as a silicon oxide (SiOₓ)-based inorganic film, but is not limited thereto.

Each of ninth vias VA9 may penetrate through the ninth interlayer insulating film INS9 to be connected to the exposed eight conductive layer ML8. Each of the ninth vias VA9 may be made of copper (Cu), aluminum (Al), tungsten (W), molybdenum (Mo), chromium (Cr), gold (Au), titanium (Ti), nickel (Ni), and/or neodymium (Nd), and/or alloys thereof. A thickness of the ninth via VA9 may be approximately 16500 Å.

The reflective electrode layer RL may be disposed on the ninth interlayer insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 8.

Each of the first reflective electrodes RL1 may be disposed on the ninth interlayer insulating film INS9 and may be connected to the ninth via VA9. Each of the first reflective electrodes RL1 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the first reflective electrodes RL1 may include titanium nitride (TiN).

Each of the second reflective electrodes RL2 may be disposed on the first reflective electrode RL1. Each of the second reflective electrodes RL2 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the second reflective electrodes RL2 may include aluminum (Al).

Each of the third reflective electrodes RL3 may be disposed on the second reflective electrode RL2. Each of the third reflective electrodes RL3 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the third reflective electrodes RL3 may include titanium nitride (TiN).

Each of the fourth reflective electrodes RL4 may be disposed on the third reflective electrode RL3. Each of the fourth reflective electrodes RL4 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the fourth reflective electrodes RL4 may include titanium (Ti).

In one or more embodiments, the second reflective electrodes RL2 are electrodes substantially reflecting light from the light emitting elements LE, and a thickness of the second reflective electrode RL2 may be greater than a thickness of the first reflective electrode RL1, a thickness of the third reflective electrode RL3, and a thickness of the fourth reflective electrode RL4. For example, the thickness of the first reflective electrode RL1, the third reflective electrode RL3, and the fourth reflective electrode RL4 may be approximately 100 Å, and the thickness of the second reflective electrode RL2 may be approximately 850 Å.

A tenth interlayer insulating film INS10 may be disposed on the ninth interlayer insulating film INS9. The tenth interlayer insulating film INS10 may be disposed between the reflective electrode layers RL adjacent to each other. The tenth interlayer insulating film INS10 may be disposed on the reflective electrode layer RL in the third sub-pixel SP3. The tenth interlayer insulating film INS10 may be formed as a silicon oxide (SiOₓ)-based inorganic film, but is not limited thereto.

An eleventh interlayer insulating film INS11 may be disposed on the tenth interlayer insulating film INS10 and the reflective electrode layer RL. The eleventh interlayer insulating film INS11 may be formed as a silicon oxide (SiOₓ)-based inorganic film, but is not limited thereto.

In at least one of the first sub-pixel SP1, the second sub-pixel SP2, and the third sub-pixel SP3, the tenth interlayer insulating film INS10 and the eleventh interlayer insulating film INS11 may not be disposed below the first electrode AND, in consideration of a resonance distance of the light emitted from the light emitting elements LE.

For example, the first electrode AND of the first sub-pixel SP1 may be directly disposed on the fourth reflective electrode RL4, and may not overlap the tenth interlayer insulating film INS10 and the eleventh interlayer insulating film INS11. The first electrode AND of the second sub-pixel SP2 may be disposed on the eleventh interlayer insulating film INS11, and the eleventh interlayer insulating film INS11 may be directly disposed on the fourth reflective electrode RL4. That is, the first electrode AND of the second sub-pixel SP2 may not overlap the tenth interlayer insulating film INS10. The first electrode AND of the third sub-pixel SP3 may be disposed on the eleventh interlayer insulating film INS11, and may overlap the tenth interlayer insulating film INS10.

In one or more embodiments, a distance between the first electrode AND and the reflective electrode layer RL may be different in each of the first sub-pixel SP1, the second sub-pixel SP2, and the third sub-pixel SP3. In order to adjust a distance from the reflective electrode layer RL to a second electrode CAT according to a main wavelength of light emitted from each of the first sub-pixel SP1, the second sub-pixel SP2, and third the sub-pixel SP3, the presence or absence of the tenth interlayer insulating film INS10 and the eleventh interlayer insulating film INS11 may be set in each of the first sub-pixel SP1, the second sub-pixel SP2, and the third sub-pixel SP3. For example, in FIG. 8, a distance between the first electrode AND and the reflective electrode layer RL in the third sub-pixel SP3 may be greater than a distance between the first electrode AND and the reflective electrode layer RL in the second sub-pixel SP2 and a distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. However, the present disclosure is not limited thereto. The distance between the first electrode AND and the reflective electrode layer RL in each of the sub-pixels SP1, SP2, and SP3 may be variously modified and designed.

In addition, it has been illustrated in FIG. 8 that the tenth interlayer insulating film INS10 and the eleventh interlayer insulating film INS11 are disposed, but a twelfth interlayer insulating film may be further disposed below the first electrode AND of the sub-pixel SP. In this case, the eleventh interlayer insulating film INS11 and the twelfth interlayer insulating film may be disposed below the first electrode AND of the second sub-pixel SP2, and the tenth interlayer insulating film INS10, the eleventh interlayer insulating film INS11, and the twelfth interlayer insulating film may be disposed below the first electrode AND of the third sub-pixel SP3.

Each of tenth vias VA10 may penetrate through the tenth interlayer insulating film INS10 and/or the eleventh interlayer insulating film INS11 in the second sub-pixel SP2 and the third sub-pixel SP3 to be connected to the exposed fourth reflective electrode RL4. Each of the tenth vias VA10 may be made of copper (Cu), aluminum (Al), tungsten (W), molybdenum (Mo), chromium (Cr), gold (Au), titanium (Ti), nickel (Ni), and/or neodymium (Nd), and/or alloys thereof. A thickness of the tenth via VA10 in the second sub-pixel SP2 may be smaller than a thickness of the tenth via VA10 in the third sub-pixel SP3.

The light emitting element layer EML may be disposed on the light emitting element backplane EBP. The light emitting element layer EML may include light emitting elements LE each including a first electrode AND, a light emitting stack IL, and a second electrode CAT, a pixel defining film PDL, and a plurality of trenches TRC.

The first electrode AND of each of the light emitting elements LE may be disposed on the tenth interlayer insulating film INS10 or the eleventh interlayer insulating film INS11 or the fourth reflective electrode RL4 and may be connected to the tenth via VA10. The first electrode AND of each of the light emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, the first electrode AND of each of the light emitting elements LE may be made of titanium nitride (TIN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3.

The first emission area EA1 may be defined as an area where the first electrode AND, the light emitting stack IL, and the second electrode CAT are sequentially stacked in the first sub-pixel SP1 to emit light. The second emission area EA2 may be defined as an area where the first electrode AND, the light emitting stack IL, and the second electrode CAT are sequentially stacked in the second sub-pixel SP2 to emit light. The third emission area EA3 may be defined as an area where the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but are not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first inorganic encapsulation layer TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

In order to prevent the first inorganic encapsulation layer TFE1 from being disconnected due to the step coverage, the first pixel defining film PDL1, the second pixel defining film PDL2, and the third pixel defining film PDL3 may have a cross-sectional structure with a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length, in a horizontal direction, of the first pixel defining film PDL1 defined by the first direction DR1 and the second direction DR2.

Each of the plurality of trenches TRC may penetrate through the first pixel defining film PDL1, the second pixel defining film PDL2, and the third pixel defining film PDL3. In each of the plurality of trenches TRC, a portion of the tenth interlayer insulating film INS10 may be trenched and the eleventh interlayer insulating film INS11 may be penetrated.

At least one trench TRC may be disposed between the sub-pixels SP1, SP2, and SP3 neighboring each other. It has been illustrated in FIG. 8 that two trenches TRC are disposed between the sub-pixels SP1, SP2, and SP3 neighboring each other, but the present disclosure is not limited thereto.

The light emitting stack IL may include a plurality of intermediate layers. It has been illustrated in FIG. 8 that the light emitting stack IL has a three-tandem structure including a first intermediate layer IL1, a second intermediate layer IL2, and a third intermediate layer IL3, but the present disclosure is not limited thereto. For example, the light emitting stack IL may have a two-tandem structure including two intermediate layers.

In the three-tandem structure, the light emitting stack IL may have a tandem structure including a plurality of intermediate layers IL1, IL2, and IL3 emitting different light. For example, the light emitting stack IL may include a first intermediate layer IL1 emitting light of a first color, a second intermediate layer IL2 emitting light of a third color, and a third intermediate layer IL3 emitting light of a second color. The first intermediate layer IL1, the second intermediate layer IL2, and the third intermediate layer IL3 may be sequentially stacked.

The first intermediate layer IL1 may have a structure in which a first hole transporting layer, a first organic light emitting layer emitting the light of the first color, and a first electron transporting layer are sequentially stacked. The second intermediate layer IL2 may have a structure in which a second hole transporting layer, a second organic light emitting layer emitting the light of the third color, and a second electron transporting layer are sequentially stacked. The third intermediate layer IL3 may have a structure in which a third hole transporting layer, a third organic light emitting layer emitting the light of the second color, and a third electron transporting layer are sequentially stacked.

A first charge generation layer for supplying charges to the second intermediate layer IL2 and supplying electrons to the first intermediate layer IL1 may be disposed between the first intermediate layer IL1 and the second intermediate layer IL2. The first charge generation layer may include an N-type charge generation layer supplying electrons to the first intermediate layer IL1 and a P-type charge generation layer supplying holes to the second intermediate layer IL2. The N-type charge generation layer may include a dopant of a metal material.

A second charge generation layer for supplying charges to the third intermediate layer IL3 and supplying electrons to the second intermediate layer IL2 may be disposed between the second intermediate layer IL2 and the third intermediate layer IL3. The second charge generation layer may include an N-type charge generation layer supplying electrons to the second intermediate layer IL2 and a P-type charge generation layer supplying holes to the third intermediate layer IL3.

The first intermediate layer IL1 may be disposed on the first electrodes AND and the pixel defining film PDL, and may be disposed on a bottom surface of each of the trenches TRC. Due to the trenches TRC, the first intermediate layer IL1 may be disconnected between the sub-pixels SP1, SP2, and SP3 neighboring each other. The second intermediate layer IL2 may be disposed on the first intermediate layer IL1. Due to the trenches TRC, the second intermediate layer IL2 may be disconnected between the sub-pixels SP1, SP2, and SP3 neighboring each other. A cavity or an empty space may be disposed between the first intermediate layer IL1 and the second intermediate layer IL2. The third intermediate layer IL3 may be disposed on the second intermediate layer IL2. The third intermediate layer IL3 may not be disconnected by the trenches TRC, and may be disposed to cover the second intermediate layer IL2 in each of the trenches TRC. That is, in the three-tandem structure, each of the plurality of trenches TRC may be a structure for disconnecting the first and second intermediate layers IL1 and IL2, the first charge generation layer, and the second charge generation layer of the light emitting element layer EML between the sub-pixels SP1, SP2, and SP3 neighboring each other. In addition, in the two-tandem structure, each of the plurality of trenches TRC may be a structure for disconnecting a charge generation layer disposed between a lower intermediate layer and an upper intermediate layer.

In order to stably disconnect the first and second intermediate layers IL1 and IL2 of the light emitting element layer EML between the sub-pixels SP1, SP2, and SP3 neighboring each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the light emitting element layer EML between the sub-pixels SP1, SP2, and SP3 neighboring each other, other structures may exist instead of the trenches TRC. For example, instead of the trenches TRC, partition walls having a reverse tapered shape may be disposed on the pixel defining film PDL.

The number of intermediate layers IL1, IL2, and IL3 emitting the different light is not limited to that illustrated in FIG. 8. For example, the light emitting stack IL may include two intermediate layers. In this case, any one of the two intermediate layers may be substantially the same as the first intermediate layer IL1, and the other of the two intermediate layers may include a second hole transporting layer, a second organic light emitting layer, a third organic light emitting layer, and a second electron transporting layer. In this case, a charge generation layer for supplying electrons to any one intermediate layer and supplying charges to the other intermediate layer may be disposed between the two intermediate layers.

In addition, it has been illustrated in FIG. 8 that the first to third intermediate layers IL1, IL2, and IL3 are all disposed in the first emission area EA1, the second emission area EA2, and the third emission area EA3, but the present disclosure is not limited thereto. For example, the first intermediate layer IL1 may be disposed in the first emission area EA1, and may not be disposed in the second emission area EA2 and the third emission area EA3. In addition, the second intermediate layer IL2 may be disposed in the second emission area EA2, and may not be disposed in the first emission area EA1 and the third emission area EA3. In addition, the third intermediate layer IL3 may be disposed in the third emission area EA3, and may not be disposed on the first emission area EA1 and the second emission area EA2. In this case, first to third color filters CF1, CF2, and CF3 of the color filter layer CFL may be omitted.

The second electrode CAT may be disposed on the third intermediate layer IL3. The second electrode CAT may be disposed on the third intermediate layer IL3 in each of the plurality of trenches TRC. The second electrode CAT may be made of a transparent conductive material (TCO) such as indium tin oxide (ITO) and/or indium zinc oxide (IZO) capable of transmitting light therethrough or a semi-transmissive conductive material such as magnesium (Mg), silver (Ag), and/or an alloy of magnesium (Mg) and/or silver (Ag). When the second electrode CAT is made of the semi-transmissive conductive material, light emission efficiency of each of the first to third sub-pixels SP1, SP2, and SP3 may be increased by a micro cavity.

The encapsulation layer TFE may be disposed on the light emitting element layer EML. The encapsulation layer TFE may include at least one inorganic encapsulation layer TFE1 and TFE3 in order to prevent oxygen and/or moisture from permeating into the light emitting element layer EML. In addition, the encapsulation layer TFE may include at least one organic film in order to protect the light emitting element layer EML from foreign materials such as dust. For example, the encapsulation layer TFE may include a first inorganic encapsulation layer TFE1, an organic encapsulation layer TFE2, and a second inorganic encapsulation layer TFE3.

The first inorganic encapsulation layer TFE1 may be disposed on the second electrode CAT, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed as multiple films in which one or more inorganic films of a silicon nitride (SiNₓ) layer, a silicon oxynitride (SiOₓN_{y}) layer, a silicon oxide (SiOₓ) layer, a titanium oxide (TiOₓ) layer, and/or an aluminum oxide (AlOₓ) layer are alternately stacked. The organic encapsulation layer TFE2 may be made of a monomer. Alternatively, the organic encapsulation layer TFE2 may be an organic film made of an acrylic resin, an epoxy resin, a phenolic resin, a polyamide resin, a polyimide resin, and/or the like.

The adhesive layer ADL may be disposed on the encapsulation layer TFE. The adhesive layer ADL may be a layer for adhering the encapsulation layer TFE and a layer disposed thereon to each other. The adhesive layer ADL may be a double-sided adhesive member. In addition, the adhesive layer ADL may be a transparent adhesive member such as a transparent adhesive or a transparent adhesive resin.

The color filter layer CFL, the lens array layer LNS, and the cover layer DCL may be disposed on the adhesive layer ADL. The color filter layer CFL, the lens array layer LNS, and the cover layer DCL may constitute an optical layer of the display panel 100.

The color filter layer CFL may include a plurality of color filters CF1, CF2, and CF3, and may be disposed on the adhesive layer ADL. The first color filter CF1 may overlap the first emission area EA1 of the first sub-pixel SP1. The first color filter CF1 may transmit the light of the first color, that is, the light of the red wavelength band, therethrough. The first color filter CF1 may transmit the light of the first color from among light emitted from the first emission area EA1 therethrough.

The second color filter CF2 may overlap the second emission area EA2 of the second sub-pixel SP2. The second color filter CF2 may transmit the light of the second color, that is, the light of the green wavelength band, therethrough. Therefore, the second color filter CF2 may transmit the light of the second color from among light emitted from the second emission area EA2 therethrough.

The third color filter CF3 may overlap the third emission area EA3 of the third sub-pixel SP3. The third color filter CF3 may transmit the light of the third color, that is, the light of the blue wavelength band, therethrough. Therefore, the third color filter CF3 may transmit the light of the third color from among light emitted from the third emission area EA3 therethrough.

The lens array layer LNS may be disposed on the color filter layer CFL in the display area DAA. The lens array layer LNS may include a plurality of lenses disposed in the display area DAA. Each of the plurality of lenses may be disposed on the first color filter CF1, the second color filter CF2, and the third color filter CF3. Each of the plurality of lenses may be a structure for increasing a ratio of light directed to a front surface of the display device 10. Each of the plurality of lenses may have a cross-sectional shape convex in an upward direction.

The cover layer DCL may be disposed on the lens array layer LNS. The cover layer DCL may be directly disposed on the plurality of lenses of the lens array layer LNS. The cover layer DCL may have a suitable refractive index (e.g., a predetermined refractive index) so that light travels in the third direction DR3 at an interface between the plurality of lenses and the cover layer DCL. In addition, the cover layer DCL may be a planarizing layer. The cover layer DCL may be an organic film made of an acrylic resin, an epoxy resin, a phenolic resin, a polyamide resin, a polyimide resin, and/or the like.

In one or more embodiments, a polarizing plate may be disposed on the cover layer DCL. The polarizing plate may be a structure for preventing deterioration in visibility due to external light reflection. The polarizing plate may include a linear polarizing plate and a phase retardation film. For example, the phase retardation film may be a N/4 plate (quarter-wave plate), but is not limited thereto. However, when visibility due to external light reflection is sufficiently improved by the first to third color filters CF1, CF2, and CF3, the polarizing plate may be omitted.

As illustrated in FIG. 8, by forming the light emitting element backplane EBP and the light emitting element layer EML on the semiconductor substrate SSUB on which the plurality of transistors are formed, a size of the plurality of pixels PX may be significantly reduced, and thus, the display device 10 displaying a high-resolution image may be provided.

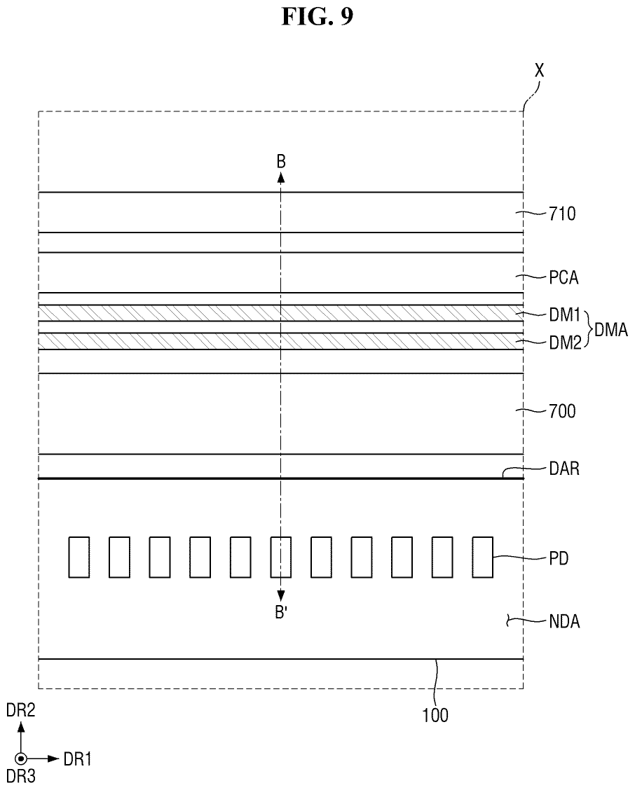

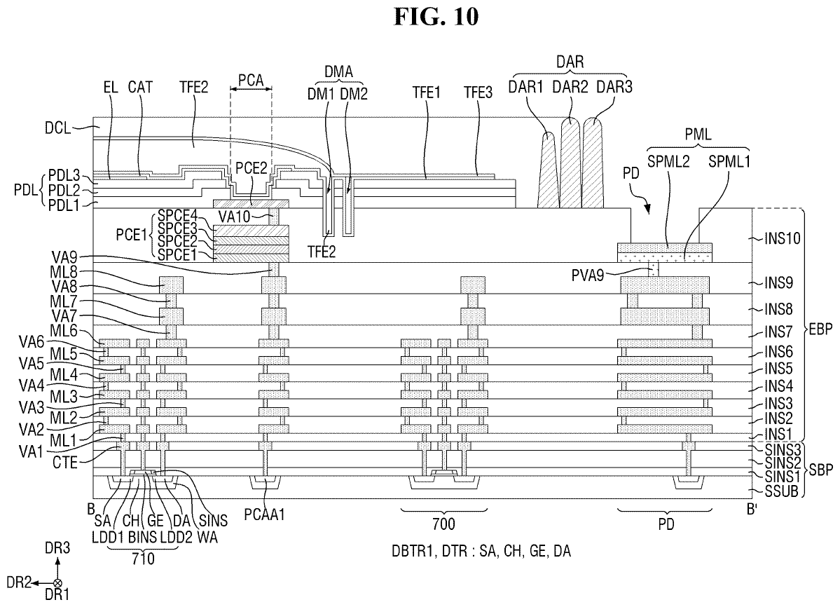

FIG. 9 is an enlarged view of an area X of FIG. 4. FIG. 10 is a schematic cross-sectional view taken along the line B-B′ of FIG. 9.

The area X of FIG. 4 may be an area disposed on the lower side of the display area DAA, which is one side of the display area DAA in the second direction DR2. In FIGS. 9 and 10, the first distribution circuit 710, the power connection portion PCA, the dam DMA, the data driver 700, the pad PD, and the sealing dam structure DAR disposed on the lower side of the display area DAA are illustrated.

Referring to FIGS. 9 and 10, on the lower side of the display area DAA, the first distribution circuit 710, the power connection portion PCA, the dam DMA, the data driver 700, the sealing dam structure DAR, and the pad PD may be sequentially disposed along the second direction DR2. However, the present disclosure is not limited thereto. In one or more embodiments, the power connection portion PCA may overlap the first distribution circuit 710 or the data driver 700 in the thickness direction (e.g., the third direction DR3), and the dam DMA may overlap the first distribution circuit 710 and/or the data driver 700 in the thickness direction (e.g., the third direction DR3).

The first distribution circuit 710 may include a plurality of first distribution transistors DBTR1. Each of the plurality of first distribution transistors DBTR1 may be formed substantially the same as the pixel transistors PTR described with reference to FIG. 8, and a detailed description of the plurality of first distribution transistors DBTR1 is thus omitted. In addition, first to eighth conductive layers ML1 to ML8 and first to eighth vias VA1 to VA8 electrically connected to the plurality of first distribution transistors DBTR1 are also substantially the same as those described with reference to FIG. 8, and a detailed description thereof is thus omitted.

The power connection portion PCA includes a first power connection area PCAA1 of the semiconductor substrate SSUB, a first power connection electrode PCE1, and a second power connection electrode PCE2.

The first driving voltage VSS may be applied to the first power connection area PCAA1 of the semiconductor substrate SSUB.

The first power connection electrode PCE1 may be disposed on the ninth interlayer insulating film INS9. The first power connection electrode PCE1 may be connected to the first power connection area PCAA1 of the semiconductor substrate SSUB through the first to eighth conductive layers ML1 to ML8 and the first to ninth vias VA1 to VA9.

The first power connection electrode PCE1 may include first to fourth sub-power connection electrodes SPCE1 to SPCE4. The first to fourth sub-power connection electrodes SPCE1 to SPCE4 of the first power connection electrode PCE1 may be substantially the same as the first to fourth reflective electrodes RL1 to RL4 of the reflective electrode layer RL. That is, the first sub-power connection electrode SPCE1 may correspond to the first reflective electrode RL1, the second sub-power connection electrode SPCE2 may correspond to the second reflective electrode RL2, the third sub-power connection electrode SPCE3 may correspond to the third reflective electrode RL3, and the fourth sub-power connection electrode SPCE4 may correspond to the fourth reflective electrode RL4.

The second power connection electrode PCE2 may be disposed on the tenth interlayer insulating film INS10. The second power connection electrode PCE2 may be connected to the first power connection electrode PCE1 through the tenth via VA10. The second power connection electrode PCE2 may include substantially the same material as the first electrode AND of the light emitting element LE. The second power connection electrode PCE2 may be partitioned by the pixel defining film PDL. The second electrode CAT of the light emitting element LE may be connected to the second power connection electrode PCE2 exposed without being covered by the pixel defining film PDL.

The dam DMA may include a first sub-dam DM1 and a second sub-dam DM2. The first sub-dam DM1 and the second sub-dam DM2 may be substantially the same as the trenches TRC. Each of the first sub-dam DM1 and the second sub-dam DM2 may penetrate through the first pixel defining film PDL1, the second pixel defining film PDL2, and the third pixel defining film PDL3. In each of the first sub-dam DM1 and the second sub-dam DM2, a portion of the tenth interlayer insulating film INS10 may be trenched.

In each of the first sub-dam DM1 and the second sub-dam DM2, the first inorganic encapsulation layer TFE1 may be disposed on a bottom surface, the organic encapsulation layer TFE2 may be disposed on the first inorganic encapsulation layer TFE1, and the second inorganic encapsulation layer TFE3 may be disposed on the organic encapsulation layer TFE2. The organic encapsulation layer TFE2 may be disposed to fill a portion of each of the first sub-dam DM1 and the second sub-dam DM2. Alternatively, the organic encapsulation layer TFE2 may not be disposed in each of the first sub-dam DM1 and the second sub-dam DM2. That is, the first inorganic encapsulation layer TFE1 and the second inorganic encapsulation layer TFE3 may be disposed in each of the first sub-dam DM1 and the second sub-dam DM2.

Due to the first sub-dam DM1 and the second sub-dam DM2, it is possible to prevent the organic encapsulation layer TFE2 from flowing to the pad portion PDA to cover the pads PD. When the organic encapsulation layer TFE2 covers the pads PD, the pads PD may not be electrically connected to the circuit board 300.

The data driver 700 may include a plurality of data transistors DTR. Each of the plurality of data transistors DTR may be formed substantially the same as the pixel transistors PTR described with reference to FIG. 8, and a detailed description of the plurality of data transistors DTR is thus omitted. In addition, first to eighth conductive layers ML1 to ML8 and first to eighth vias VA1 to VA8 electrically connected to the plurality of data transistors DTR are also substantially the same as those described with reference to FIG. 8, and a detailed description thereof is thus omitted.

The sealing dam structure DAR may be disposed on the tenth interlayer insulating film INS10. The sealing dam structure DAR may be disposed outside the dam DMA and the data driver 700 in the non-display area NDA so as to be around (e.g., to surround) the dam DMA and the data driver 700. The sealing dam structure DAR may be disposed outside the encapsulation layer TFE and may be formed to have a suitable height (e.g., a predetermined height) to form a space in which the cover layer DCL is disposed. In one or more embodiments, a height of the sealing dam structure DAR may be greater than a depth of the dam DMA. Similar to the dam DMA serving to prevent the organic encapsulation layer TFE2 of the encapsulation layer TFE from overflowing, the sealing dam structure DAR may prevent a material of the cover layer DCL from overflowing. As an example, the sealing dam structure DAR may be disposed to be spaced (or spaced apart) from an outer side surface of the pixel defining film PDL, and the cover layer DCL may be filled between the sealing dam structure DAR and the outer side surface of the pixel defining film PDL.

According to one or more embodiments, the sealing dam structure DAR of the display device 10 may include a plurality of sealing dams DAR1, DAR2, and DAR3. The plurality of sealing dams DAR1, DAR2, and DAR3 may be disposed to be around (e.g., to surround) the display area DAA or other sealing dams DAR1, DAR2, and DAR3 disposed inside. For example, the sealing dam structure DAR may include a first sealing dam DAR1 surrounding the display area DAA, a second sealing dam DAR2 surrounding the first sealing dam DAR1, and a third sealing dam DAR3 surrounding the second sealing dam DAR2. The first to third sealing dams DAR1, DAR2, and DAR3 may be sequentially disposed toward the outside of the display panel 100 based on the display area DAA. The plurality of sealing dams DAR1, DAR2, and DAR3 may be disposed to be in contact with each other, but are not limited thereto. The sealing dams DAR1, DAR2, and DAR3 may also be disposed to be spaced (or spaced apart) from each other by a suitable interval (e.g., a predetermined interval).

It has been illustrated in FIG. 10 that the sealing dam structure DAR includes three sealing dams DAR1, DAR2, and DAR3, but the present disclosure is not limited thereto. The sealing dam structure DAR may include at least one sealing dam DAR1, DAR2, and DAR3, the innermost sealing dam (e.g., the first sealing dam) may surround the display area DAA, and the outermost sealing dam (e.g., the third sealing dam DAR3) may surround inner sealing dams disposed inside the outermost sealing dam.

The sealing dam structure DAR may include the sealing dams DAR1, DAR2, and DAR3 having suitable heights (e.g., predetermined heights), surround the display area DAA, and form a space where the cover layer DCL is disposed. As described later, the cover layer DCL may be formed by applying a resin having fluidity to the area surrounded by the sealing dam structure DAR and then curing the resin. The resin may be applied to the area surrounded by the sealing dam structure DAR and then stamped, such that an upper surface of the resin may be planarized, and depending on an amount of applied resin, the resin having the fluidity may be applied so as to overflow the sealing dam structure or so as not to completely fill the area surrounded by the sealing dam structure DAR. In the display device 10 according to one or more embodiments, the sealing dam structure DAR includes the plurality of sealing dams DAR1, DAR2, and DAR3, and the resin may thus be controlled to overflow at least the innermost sealing dam (e.g., the first sealing dam DAR1), but not to overflow the outermost sealing dam (e.g., the third sealing dam DAR3). Accordingly, a position and a shape of the cover layer DCL formed by curing the resin may be smoothly controlled, and appearance quality of the display device 10 may be improved. A more detailed description thereof will be provided later.

Each of the pads PD may include a pad conductive layer PML. The pad conductive layer PML may include a first sub-pad conductive layer SPML1 and a second sub-pad conductive layer SPML2. The first sub-pad conductive layer SPML1 may be made of copper (Cu), aluminum (Al), tungsten (W), molybdenum (Mo), chromium (Cr), gold (Au), titanium (Ti), nickel (Ni), and/or neodymium (Nd), and/or alloys thereof. The second sub-pad conductive layer SPML2 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, the first sub-pad conductive layer SPML1 may be made of aluminum (Al), and may have a thickness of approximately 12,000 Å. In addition, the second sub-pad conductive layer SPML2 may be made of titanium nitride (TiN), and may have a thickness of approximately 600 Å. A thickness of the pad conductive layer PML may be greater than a thickness of the reflective electrode layer RL.

A portion of an upper surface of the pad conductive layer PML of the pads PD may be exposed without being covered by the tenth interlayer insulating film INS10. The first sub-pad conductive layer SPML1 may be connected to a pad via PVA9 penetrating through the ninth interlayer insulating film INS9 to be connected to the eighth conductive layer ML8.

The encapsulation layer TFE and the cover layer DCL may also be disposed in a portion of the non-display area NDA positioned on the lower side of the display area DAA. The organic encapsulation layer TFE2 of the encapsulation layer TFE may be disposed up to the inside of the dam DMA, while the inorganic encapsulation layers TFE1 and TFE3 of the encapsulation layer TFE may be disposed up to the outside of the dam DMA to form an inorganic bonding area. The cover layer DCL may be disposed up to the outside of the inorganic encapsulation layers TFE1 and TFE3 of the encapsulation layer TFE.

The cover layer DCL may be disposed up to the non-display area NDA beyond the display area DAA so as to completely cover at least the display area DAA. The cover layer DCL may be disposed in a space surrounded by the sealing dam structure DAR, and may have a lower surface in contact with the encapsulation layer TFE and the pixel defining film PDL and side surfaces in contact with the sealing dam structure DAR. The cover layer DCL may be disposed to be around (e.g., to surround) outer surfaces of components disposed on the backplanes SBP and EBP to fill a step due to these components while protecting these components. In one or more embodiments, the cover layer DCL may also be partially disposed in the non-display area NDA positioned on the upper side of the display area DAA.

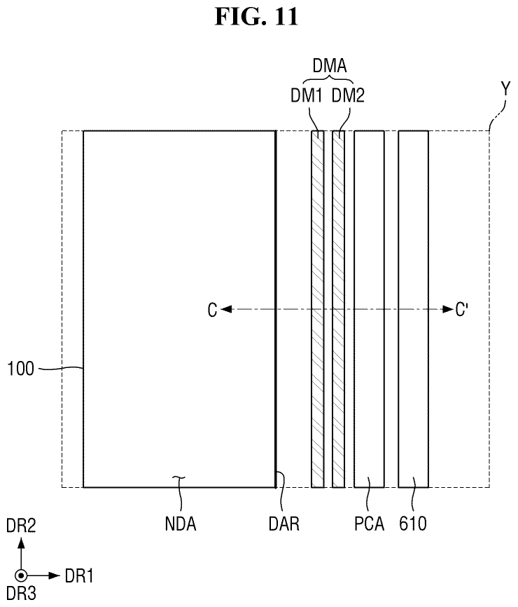

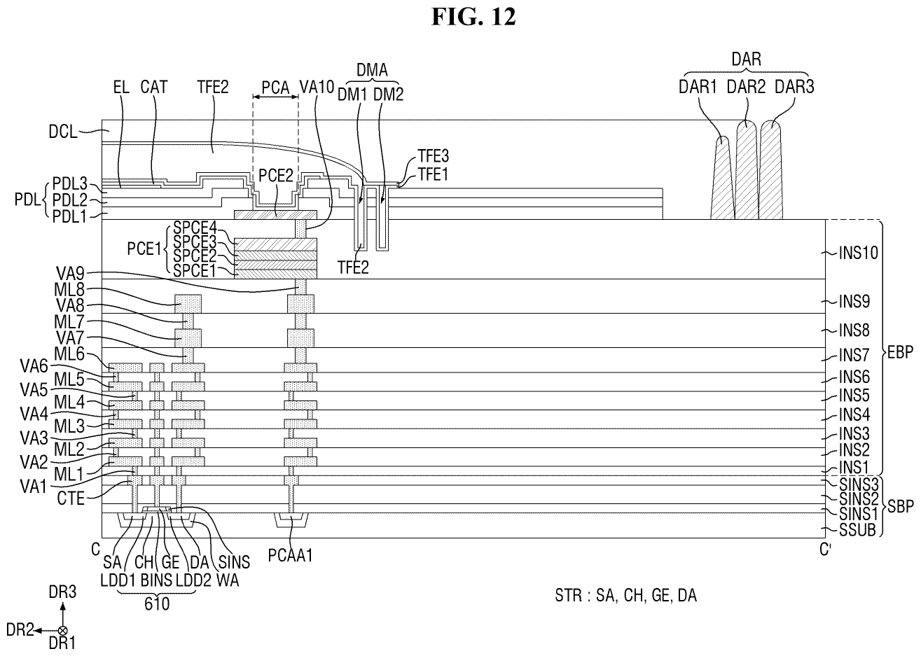

FIG. 11 is an enlarged view of an area Y of FIG. 4. FIG. 12 is a schematic cross-sectional view taken along the line C-C′ of FIG. 11.

The area Y of FIG. 4 may be an area disposed on the left side of the display area DAA, which is one side of the display area DAA in the first direction DR1. In FIGS. 11 and 12, the scan driver 610, the power connection portion PCA, and the dam DMA disposed on the left side of the display area DAA are illustrated.

Referring to FIGS. 11 and 12, on the left side of the display area DAA, the scan driver 610, the power connection portion PCA, the dam DMA, and the sealing dam structure DAR may be sequentially disposed along the first direction DR1. However, the present disclosure is not limited thereto, and the power connection portion PCA may overlap the scan driver 610 in the thickness direction, and the dam DMA may overlap the scan driver 610 in the thickness direction.

The scan driver 610 may include a plurality of scan transistors STR. Each of the plurality of scan transistors STR may be formed substantially the same as the pixel transistors PTR described with reference to FIG. 8, and a detailed description of the plurality of scan transistors STR is thus omitted. In addition, first to eighth conductive layers ML1 to ML8 and first to eighth vias VA1 to VA8 electrically connected to the plurality of scan transistors STR are also substantially the same as those described with reference to FIG. 8, and a detailed description thereof is thus omitted.

The power connection portion PCA, the dam DMA, and the sealing dam structure DAR are substantially the same as those described with reference to FIGS. 9 and 10, and a detailed description thereof is thus omitted.

In addition, an area disposed on the second side of the display area DAA is substantially the same as that illustrated in FIGS. 11 and 12 except that the scan driver 610 is replaced with the emission driver 620, and a description thereof is thus omitted.

The encapsulation layer TFE and the cover layer DCL may also be disposed in a portion of the non-display area NDA positioned on the left side of the display area DAA. The organic encapsulation layer TFE2 of the encapsulation layer TFE may be disposed up to the inside of the dam DMA, while the inorganic encapsulation layers TFE1 and TFE3 of the encapsulation layer TFE may be disposed up to the outside of the dam DMA to form an inorganic bonding area. The cover layer DCL may be disposed up to the outside of the inorganic encapsulation layers TFE1 and TFE3 of the encapsulation layer TFE. The cover layer DCL may be disposed up to the non-display area NDA beyond the display area DAA so as to completely cover the display area DAA. In one or more embodiments, the cover layer DCL may also be partially disposed in the non-display area NDA positioned on the right side of the display area DAA.

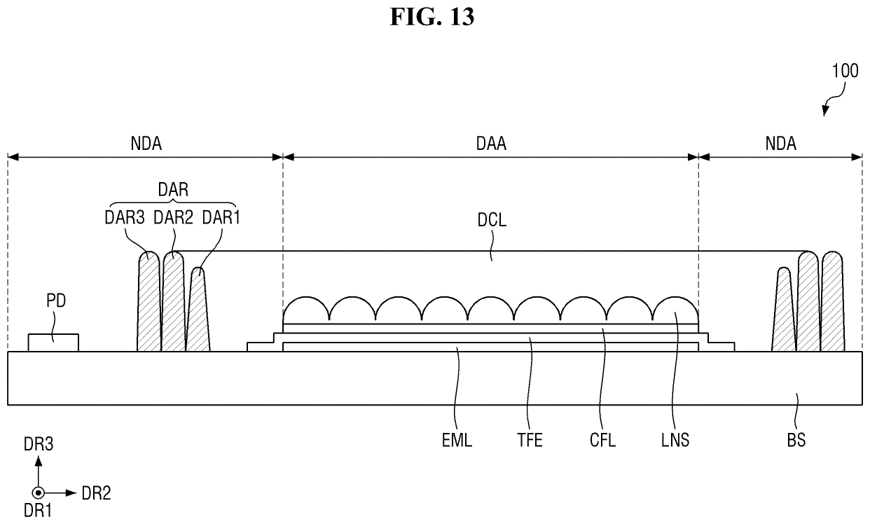

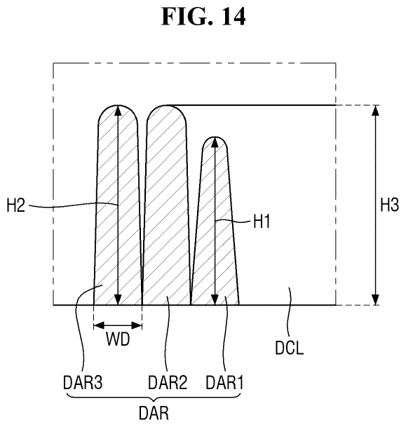

FIG. 13 is a schematic cross-sectional view of the display panel according to one or more embodiments taken along a second direction (e.g., DR2). FIG. 14 is a cross-sectional view illustrating a sealing dam structure of the display device according to one or more embodiments in more detail. FIG. 14 illustrates a relative structure of the plurality of sealing dams DAR1, DAR2, and DAR3 of the sealing dam structure DAR and a relative arrangement of the plurality of sealing dams DAR1, DAR2, and DAR3 of the sealing dam structure DAR with the cover layer DCL in more detail.

Referring to FIGS. 13 and 14, the display device 10 may include the sealing dam structure DAR and the cover layer DCL disposed on a base substrate BS of the display panel 100. The light emitting element layer EML, the encapsulation layer TFE, the color filter layer CFL, and the lens array layer LNS may be disposed on the base substrate BS of the display panel 100. The base substrate BS may include the semiconductor backplane SBP and the light emitting element backplane EBP described above with reference to FIG. 8. A description thereof is the same as that described above, and a detailed description is thus omitted.

The sealing dam structure DAR may be disposed in the non-display area NDA and disposed to be around (e.g., to surround) components of the display panel 100 except for the pad PD. The sealing dam structure DAR may form an area where the cover layer DCL protecting components disposed in the display panel 100 is disposed. The sealing dam structure DAR may have a greater height than the lens array layer LNS from the base substrate BS. In addition, the sealing dam structure DAR may be formed to be partially spaced (or spaced apart) from the encapsulation layer TFE so that the cover layer DCL may also surround side surfaces of the encapsulation layer TFE. The encapsulation layer TFE may form the inorganic bonding area at an outer portion of the dam DMA, and the sealing dam structure DAR may be formed in an area spaced (or spaced apart) from the inorganic bonding area. In one or more embodiments, the sealing dam structure DAR may include a polymer resin.

The cover layer DCL may be disposed in an area surrounded by the sealing dam structure DAR to planarize an upper surface of the display panel 100. A height of the cover layer DCL may be the same as a height of the sealing dam DAR1, DAR2, or DAR3 having the greatest height in the sealing dam structure DAR, and an upper surface of the cover layer DCL may be substantially coplanar with an upper surface of the sealing dam structure DAR. The cover layer DCL may cover at least components disposed in the display area DAA, and may also be disposed in a portion of the non-display area NDA to be around (e.g., to surround) these components. A lower surface of the cover layer DCL may be in contact with the lens array layer LNS, the encapsulation layer TFE, and the base substrate BS, and side surfaces of the cover layer DCL may be in contact with the sealing dam structure DAR. The cover layer DCL may protect the components disposed in the display panel 100 and at the same time, may serve to planarize the upper surface of the display panel 100 while filling a step due to components disposed on the base substrate BS. In one or more embodiments, the cover layer DCL may include a transparent polymer resin.

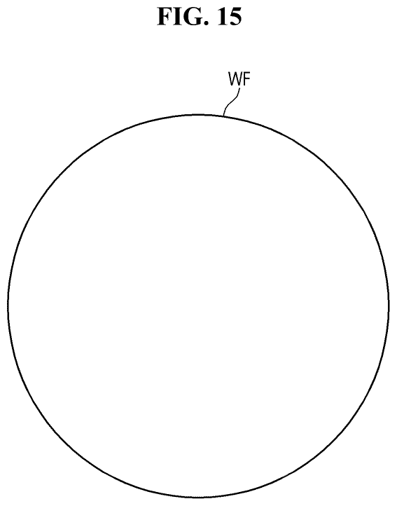

In the display device 10, the display panel 100 includes the sealing dam structure DAR and the cover layer DCL that are made of the polymer resin, such that a separate hard cover member may be omitted. As described later, fabricating processes of the display device 10 may include a process of forming a plurality of layers on a wafer substrate WF (see FIG. 15) and then dividing the wafer substrate to form the display device 10. Because the display panel 100 of the display device 10 does not include a separate cover member, it is possible to prevent breakage of the cover member in a process of dividing the wafer substrate or damage to the display panel 100 due to the breakage of the cover member. Furthermore, in a process of forming the cover layer DCL including the polymer resin, a process of smoothly planarizing the upper surface rather than a cutting or etching process that causes damage to the display panel 100 is performed, and thus, surface quality of the display panel 100 may also be improved.

According to one or more embodiments, the sealing dam structure DAR may include a plurality of sealing dams DAR1, DAR2, and DAR3. The plurality of sealing dams DAR1, DAR2, and DAR3 may be formed to have suitable heights (e.g., a predetermined heights), and form a space where the cover layer DCL is disposed. As an example, the sealing dam structure DAR may include a first sealing dam DAR1, a second sealing dam DAR2, and a third sealing dam DAR3 disposed to be around (e.g., to surround) the display area DAA or other sealing dams DAR1, DAR2, and DAR3 disposed inside. The first sealing dam DAR1 of the plurality of sealing dams DAR1, DAR2, and DAR3 may be the innermost sealing dam disposed closest to the display area DAA, and the third sealing dam DAR3 of the plurality of sealing dams DAR1, DAR2, and DAR3 may be the outermost sealing dam disposed furthest from the display area DAA. The second sealing dam DAR2 may be an intermediate sealing dam disposed between the first sealing dam DAR1 and the third sealing dam DAR3. When the sealing dam structure DAR of the display device 10 includes a larger number of sealing dams, a plurality of second sealing dams DAR2, which are intermediate sealing dams, may be disposed. Alternatively, when the sealing dam structure DAR includes two sealing dams, the intermediate sealing dam may be omitted, and the sealing dam structure DAR may include only the innermost sealing dam and the outermost sealing dam.

According to one or more embodiments, at least some of the plurality of sealing dams DAR1, DAR2, and DAR3 of the sealing dam structure DAR may be surrounded or covered by the cover layer DCL. However, an outer surface of the third sealing dam DAR3, which is the outermost sealing dam of the plurality of sealing dams DAR1, DAR2, and DAR3, may not be in contact with the cover layer DCL or the third sealing dam DAR3 may not be covered by the cover layer DCL.

For example, at least the innermost sealing dam of the plurality of sealing dams DAR1, DAR2, and DAR3 may be covered by the cover layer DCL or the cover layer DCL may be disposed beyond the innermost sealing dam. On the other hand, the cover layer DCL may not go beyond at least the outermost sealing dam of the plurality of sealing dams DAR1, DAR2, and DAR3. The first sealing dam DAR1 is the innermost sealing dam, and the cover layer DCL may be disposed beyond the first sealing dam DAR1. At least a portion of the cover layer DCL may be disposed between the first sealing dam DAR1 and the second sealing dam DAR2. In one or more embodiments, the cover layer DCL may be disposed beyond the second sealing dam DAR2, and a portion of the cover layer DCL may be disposed between the second sealing dam DAR2 and the third sealing dam DAR3. The third sealing dam DAR3 is the outermost sealing dam, and the cover layer DCL may be disposed so as not to go beyond the third sealing dam DAR3.

The plurality of sealing dams DAR1, DAR2, and DAR3 may have a structure in which the cover layer DCL is disposed beyond at least the innermost sealing dam, but does not go beyond the outermost sealing dam. The cover layer DCL may be disposed to completely fill a space formed by the innermost sealing dam, and may be disposed so as not to go beyond a space formed by the outermost sealing dam. Accordingly, even though dispersion occurs in an amount of resin applied when the cover layer DCL is formed, a shape of the cover layer DCL that is finally disposed may be uniformly controlled, and an appearance quality of the display device 10 may be improved.

According to one or more embodiments, the display device 10 may include the sealing dams DAR1, DAR2, and DAR3 that include the same material but have different heights. For example, a height H1 of the first sealing dam DAR1, which is the innermost sealing dam, may be smaller than a height H2 of the third sealing dam DAR3, which is the outermost sealing dam. The height H2 of the third sealing dam DAR3 may be the same as a height of the second sealing dam DAR2, which is the intermediate sealing dam, and a maximum thickness H3 of the cover layer DCL may also be the same as the height of the second sealing dam DAR2 and the third sealing dam DAR3. The cover layer DCL may be formed to completely cover the first sealing dam DAR1, and may partially fill a space between the first sealing dam DAR1 and the second sealing dam DAR2. However, the cover layer DCL may be disposed so as not to go beyond the second sealing dam DAR2, and may not be disposed between the second sealing dam DAR2 and the third sealing dam DAR3.

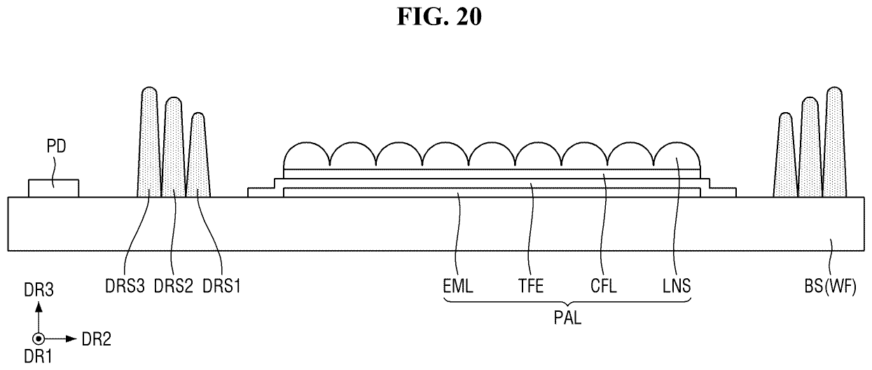

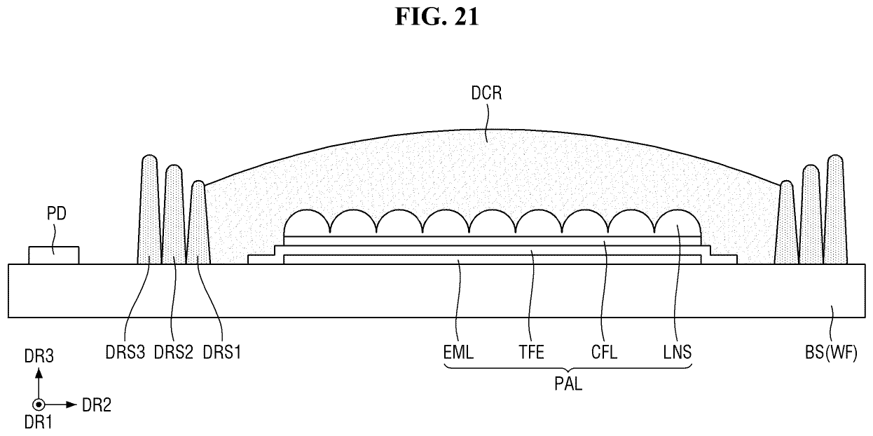

The first to third sealing dams DAR1, DAR2, and DAR3 may be formed through a process of forming sealing dam resins DRS1, DRS2, and DRS3 (see FIG. 20) respectively forming first to third sealing dams DAR1, DAR2, and DAR3, applying a resin DCR (see FIG. 21) forming the cover layer DCL, and then curing these resins while performing a stamping process. In the stamping process, the resin forming the cover layer DCL may fill an area surrounded by the sealing dam resins DRS1, DRS2, and DRS3, and the cover layer DCL may be formed in the area filled with the resin. As described later, the sealing dam resins DRS1, DRS2, and DRS3 respectively forming the first to third sealing dams DAR1, DAR2, and DAR3 may have different heights, and heights of some sealing dam resins DRS1, DRS2, and DRS3 having great heights from among the sealing dam resins DRS1, DRS2, and DRS3 may become uniform in the stamping process. Accordingly, the first sealing dam DAR1 may have the smallest height H1, and the second sealing dam DAR2 and the third sealing dam DAR3 may have the same height H2. In addition, in the stamping process, the resin forming the cover layer DCL may fill the space between the first sealing dam DAR1 and the second sealing dam DAR2, and the cover layer DCL may cover the first sealing dam DAR1, but may not go beyond the second sealing dam DAR2. In fabricating processes of the display device 10, the sealing dam resins DRS1, DRS2, and DRS3 having the different heights are formed and the stamping process of forming the cover layer DCL is performed, and accordingly, the resin may be disposed so as not to go beyond the sealing dam structure DAR while completely filling the area surrounded by the sealing dam structure DAR.

However, a structure of the sealing dam structure DAR is not limited thereto. In one or more embodiments, heights and materials of the sealing dam resin DRS1, DRS2, and DRS3 may be different from those of the above-described embodiment, and accordingly, the space filled by the cover layer DCL and a relative structure of the sealing dam DAR1, DAR2, and DAR3 may also be changed. This will be described with reference to other embodiments.

In one or more embodiments, the first to third sealing dams DAR1, DAR2, and DAR3 may have the same width WD. As an example, the width WD of the first to third sealing dams DAR1, DAR2, and DAR3 may be in the range of 500 μm to 600 μm, and a total width of a portion where the sealing dam structure DAR is disposed may be 1500 μm or more. However, the present disclosure is not limited thereto, and the width WD of the first to third sealing dams DAR1, DAR2, and DAR3 and the total width of the portion where the sealing dam structure DAR is disposed may be changed depending on an area margin of the non-display area NDA of the display device 10.

Hereinafter, fabricating processes of the display device 10 will be described with reference to other drawings.

FIGS. 15-25 are views sequentially illustrating fabricating processes of the display device according to one or more embodiments.

A method of fabricating the display device 10 according to one or more embodiments may include forming a light emitting element layer EML, an encapsulation layer TFE, a color filter layer CFL, and a lens array layer LNS in each unit area of a wafer substrate WF and forming a sealing dam structure DAR surrounding the light emitting element layer EML, the encapsulation layer TFE, the color filter layer CFL, and the lens array layer LNS, forming a resin layer in an area surrounded by the sealing dam structure DAR and planarizing an upper surface of the resin layer, and forming a cover layer DCL by curing the resin layer. In the forming of the resin layer, the resin layer may be formed to spread within a space formed by the sealing dam structure DAR to fill the space formed by the sealing dam structure DAR. Subsequently, the upper surface of the resin layer may be planarized, and the cover layer DCL having a smooth upper surface may be then formed by curing the resin layer.

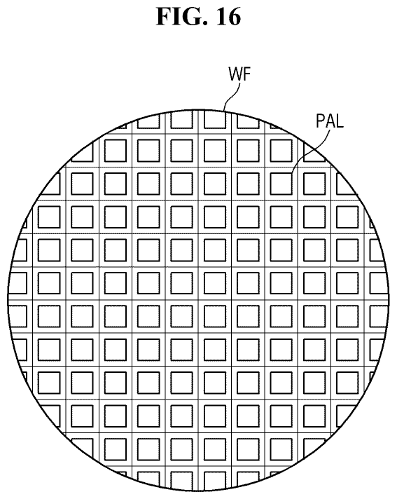

First, referring to FIGS. 15 and 16, the wafer substrate WF is prepared, and backplanes SBP and EBP, light emitting element layers EML, encapsulation layers TFE, color filter layers CFL, lens array layers LNS, pads PD, and/or the like, are formed on the wafer substrate WF to form preliminary display panels PAL. The wafer substrate WF may be a silicon substrate, a germanium substrate, and/or a silicon-germanium substrate. The wafer substrate WF may be a substrate doped with first-type impurities, and may be a mother substrate of the semiconductor substrate SSUB of the display panel 100.

A plurality of transistors PTR (e.g., pixel transistors PTR) are formed on one surface of the wafer substrate WF, and the backplanes SBP and EBP, the light emitting element layers EML, the encapsulation layers TFE, the color filter layers CFL, the lens array layers LNS, and/or the like, are formed to form the preliminary display panels PAL. A process of forming the plurality of transistors PTR on the wafer substrate WF may be a micro-semiconductor process. The backplanes SBP and EBP are formed through a micro-semiconductor process, and the light emitting element layers EML, the encapsulation layers TFE, the color filter layers CFL, and the lens array layers LNS are then formed. The wafer substrate WF may include a plurality of unit areas, and the preliminary display panel PAL may be formed in each of the unit areas. The light emitting element layers EML, the encapsulation layers TFE, the color filter layers CFL, and the lens array layers LNS may be formed through a general process. The preliminary display panel PAL may constitute the display panel 100 by forming a sealing dam structure DAR and a cover layer DCL in a process to be described later.

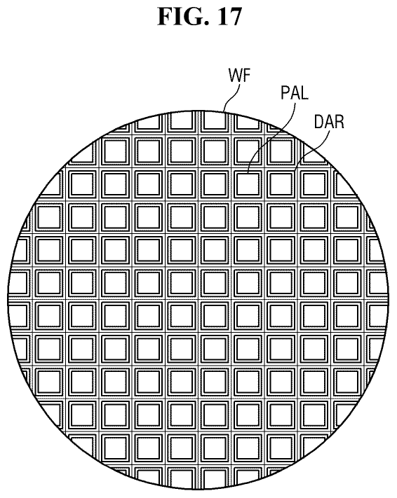

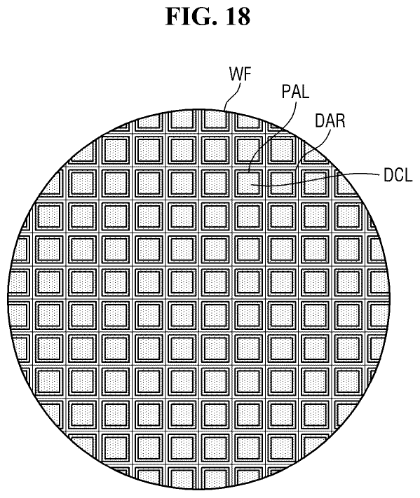

Subsequently, referring to FIGS. 17 and 18, the sealing dam structure DAR and the cover layer DCL are formed in each unit area of the wafer substrate WF. A process of forming the sealing dam structure DAR and the cover layer DCL may be a process of encapsulating the preliminary display panel PAL disposed on the wafer substrate WF. As described above, the cover layer DCL may form an upper surface of the display panel 100 by having an upper surface formed to be flat while protecting components disposed on the wafer substrate WF or the base substrate BS (see FIG. 13). As one of processes of forming the cover layer DCL, a process of forming the sealing dam structure DAR on the preliminary display panel PAL, applying a resin forming the cover layer DCL to the space formed by the sealing dam structure DAR, and planarizing and curing the resin may be performed. Each of a plurality of cover layers DCL may be formed in each of areas of the wafer substrate WF where the preliminary display panels PAL are formed, and the display panel 100 may include the cover layer DCL formed to protect the preliminary display panel PAL without a separate cover member that needs to be individually divided.

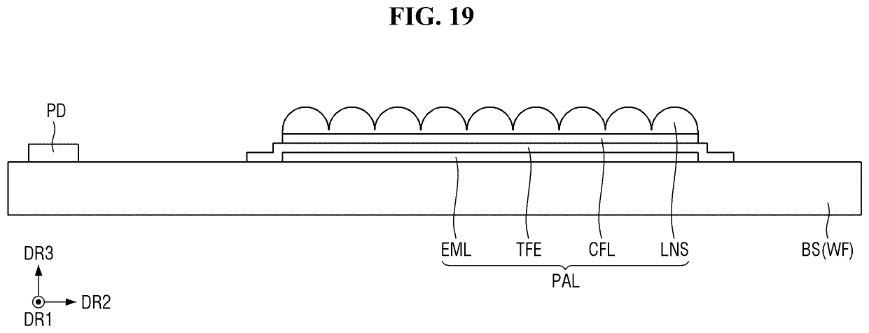

Referring to FIGS. 19 and 20, the preliminary display panel PAL is formed on the wafer substrate WF (or the base substrate BS), and a plurality of sealing dam resins DRS1, DRS2, and DRS3 are formed to be around (e.g., to surround) the preliminary display panel PAL. The pad PD may be formed to be spaced (or spaced apart) from the preliminary display panel PAL on the wafer substrate WF. The preliminary display panel PAL formed on the wafer substrate WF may include the light emitting layer EML, the encapsulation layer TFE, the color filter layer CFL, and the lens array layer LNS. However, the present disclosure is not limited thereto, and the preliminary display panel PAL may include all components of the display panel 100 except for the base substrate BS and the pad PD. The components included in the display panel 100 are the components described above with reference to FIGS. 8-13, and it may be understood that the components are briefly illustrated in FIG. 19 for convenience of explanation.

The plurality of sealing dam resins DRS1, DRS2, and DRS3 may be formed in each unit area of the wafer substrate WF where the preliminary display panel PAL and the pad PD are formed. The plurality of sealing dam resins DRS1, DRS2, and DRS3 may be disposed to be around (e.g., to surround) a portion of the unit area where the preliminary display panel PAL is disposed except for the pad PD.

The sealing dam resins DRS1, DRS2, and DRS3 may be made of polymer resins, and may be formed to have suitable heights (e.g., predetermined heights) from the wafer substrate WF.

In one or more embodiments, the plurality of sealing dam resins DRS1, DRS2, and DRS3 may include a first sealing dam resin DRS1, a second sealing dam resin DRS2, and a third sealing dam resin DRS3 that have different heights and are sequentially disposed. The first sealing dam resin DRS1 may be disposed to be around (e.g., to surround) the preliminary display panel PAL and the display area DAA, the second sealing dam resin DRS2 may be disposed to be around (e.g., to surround) the first sealing dam resin DRS1, and the third sealing dam resin DRS3 may be disposed to be around (e.g., to surround) the second sealing dam resin DRS2.

In one or more embodiments, the first sealing dam resin DRS1 may have a smaller height than the second sealing dam resin DRS2 and the third sealing dam resin DRS3, the second sealing dam resin DRS2 may have a smaller height than the third sealing dam resin DRS3, and the plurality of sealing dam resins DRS1, DRS2, and DRS3 may have heights increasing from the display area DAA toward the outside. A resin layer DCR applied in a process of forming a cover layer DCL to be described later may cover the first sealing dam resin DRS1 and fill the second sealing dam resin DRS2, but may not go beyond the second sealing dam resin DRS2 and may not come into contact with the third sealing dam resin DRS3, in a stamping process.

The plurality of sealing dam resins DRS1, DRS2, and DRS3 are fast cured-type polymer resins, and may include a material that may be formed in a shape having a height greater than a width. According to one or more embodiments, the sealing dam resins DRS1, DRS2, and DRS3 may include a material having a viscosity in the range of 50,000 to 300,000 cP and having a thixotropic index in the range of 4 to 6. The sealing dam resins DRS1, DRS2, and DRS3 may be formed in a state in which they are completely cured by having the above-described physical properties and including the fast cured-type polymer resins, and shapes of only some of the sealing dam resins DRS1, DRS2, and DRS3 may be changed in a stamping process to be described later. However, the present disclosure is not limited thereto. The sealing dam resins DRS1, DRS2, and DRS3 may be formed in a state in which they are not completely cured, and may be subjected to a stamping process to be described later, and in this case, a structure of the sealing dams DAR1, DAR2, and DAR3 and an arrangement of the cover layer DCL of the display device 10 may be changed.

Subsequently, referring to FIG. 21, the resin layer DCR forming the cover layer DCL is applied to an area surrounded by the sealing dam structure DAR on the preliminary display panel PAL. The resin layer DCR may include a polymer resin, cover the preliminary display panel PAL, and fill a space between the preliminary display panel PAL and the sealing dam structure DAR. Because the resin layer DCR is a material having fluidity before being cured, the resin layer DCR may be applied to protrude more convexly than an upper surface of the sealing dam structure DAR depending on a material difference between the resin layer DCR and the sealing dam structure DAR. However, the present disclosure is not limited thereto. The resin layer DCR may also be concavely depressed at a portion in contact with the sealing dam structure DAR.

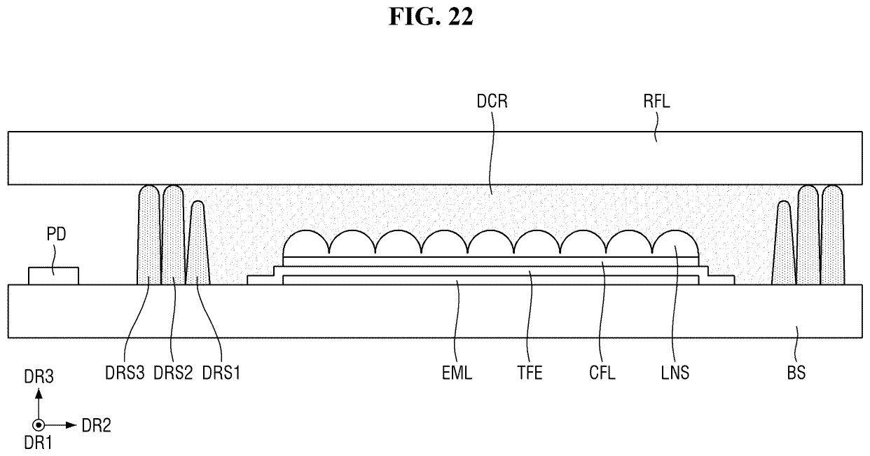

Subsequently, referring to FIG. 22, the stamping process of planarizing the upper surface of the resin layer DCR by attaching a release film RFL onto the resin layer DCR and the sealing dam structure DAR may be performed. In the present stamping process, the resin layer DCR may has the fluidity and may fill the space formed by the sealing dam structure DAR. The present stamping process may be performed as a bonding process in a vacuum chamber so that the resin layer DCR may be planarized and fill a space formed by the sealing dam structure DAR, the release film RFL, and the wafer substrate WF (or the base substrate BS).

When the release film RFL is attached onto the resin layer DCR and the sealing dam structure DAR, a pressure may be applied to an upper surface of the third sealing dam resin DRS3, and a height of the third sealing dam resin DRS3 may be partially lowered. As the plurality of sealing dam resins DRS1, DRS2, and DRS3 are formed in the cured state as described above, a height of only the third sealing dam resin DRS3 may be slightly lowered, such that the third sealing dam resin DRS3 may have the same height as the second sealing dam resin DRS2, and the second sealing dam resin DRS2 and the third sealing dam resin DRS3 may have a greater height than the first sealing dam resin DRS1. Accordingly, the resin layer DCR may spread to cover the first sealing dam resin DRS1 having a relatively small height, but may not go beyond the second sealing dam resin DRS2. The plurality of sealing dam resins DRS1, DRS2, and DRS3 may be formed in the cured state, and the second sealing dam resin DRS2 and the third sealing dam resin DRS3 may support the release film RFL while the third sealing dam resin DRS3 having the greatest height is transformed only to the extent that its height becomes the same as the height of the second sealing dam resin DRS2. Accordingly, a maximum thickness of the resin layer DCR may be the same as the heights of the second sealing dam resin DRS2 and the third sealing dam resin DRS3, and a thickness of the cover layer DCL may be controlled through as the heights of the sealing dam resins DRS1, DRS2, and DRS3.

The resin layer DCR may include a transparent polymer resin, and may spread in an area surrounded by the sealing dam resin DRS1, DRS2, and DRS3 while having fluidity. Here, when only one sealing dam resin is formed before the stamping process, the resin layer DCR may not fill an area surrounded by the sealing dam resin or may overflow into the non-display area NDA beyond the sealing dam resin in the stamping process depending on an amount of applied resin layer DCR. In addition, depending on dispersion of the stamping process, a spread degree of the resin layer DCR may be changed for each fabricating process, and ultimately, dispersion may also occur in a thickness of the cover layer DCL.

On the other hand, the method of fabricating the display device 10 according to one or more embodiments may uniformly control a spread degree of the resin layer DCR regardless of the dispersion of the stamping process by forming the plurality of sealing dam resins DRS1, DRS2, and DRS3, and may also control the thickness of the resin layer DCR through the heights of the sealing dam resin DRS1, DRS2, and DRS3. The method of fabricating the display device 10 may improve spreadability dispersion of the resin layer DCR and thickness dispersion of the cover layer DCL by forming the plurality of sealing dam resins DRS1, DRS2, and DRS3 even though there is no optimization of an amount of applied resin layer DCR, dispersion of the stamping process, and wettability characteristics due to a material difference between the resin layer DCR and the sealing dam resins DRS1, DRS2, and DRS3, and/or the like.

In one or more embodiments, one surface of the release film RFL in contact with the resin layer DCR may be surface-treated and/or coated. The release film RFL may have surface characteristics that induce the resin layer DCR to spread well so as to sufficiently fill the area surrounding the sealing dam structure DAR in a process of planarizing the resin layer DCR. The surface of the release film RFL may be subjected to hydrophilic or hydrophobic surface treatment depending on physical properties of the resin layer DCR.

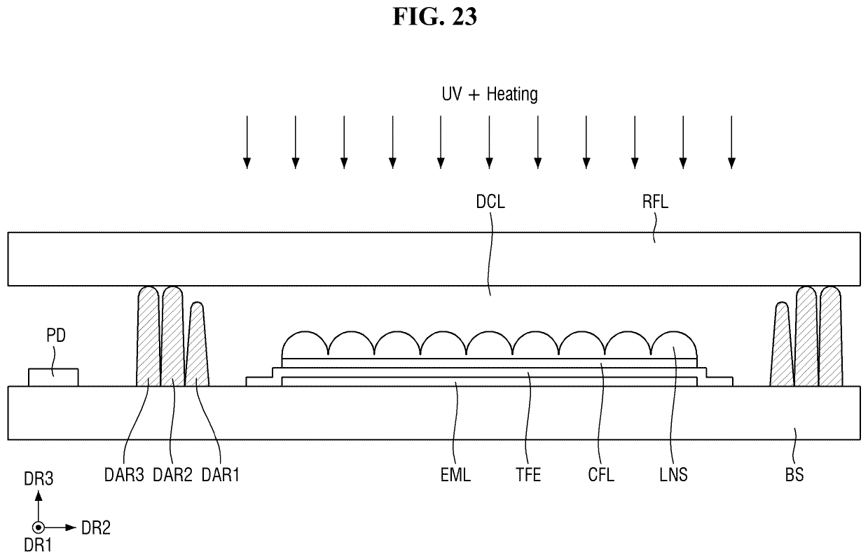

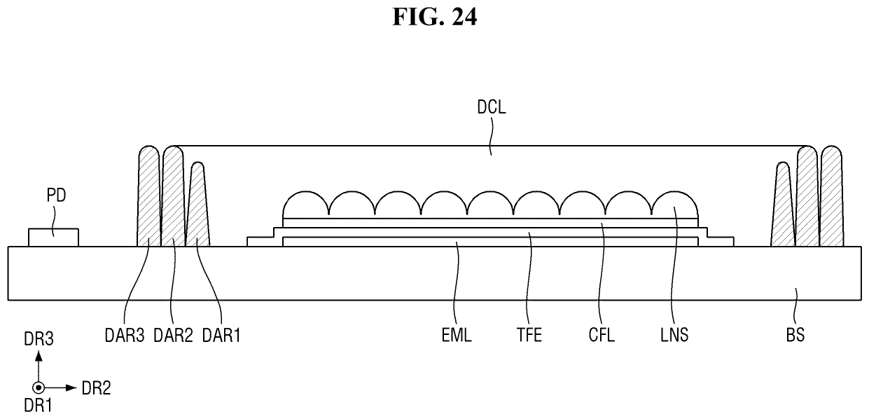

Subsequently, referring to FIGS. 23 and 24, the resin layer DCR and the sealing dam resins DRS1, DRS2, and DRS3 are cured through ultraviolet (UV) irradiation and heat treatment to form the cover layer DCL and the sealing dams DAR1, DAR2, and DAR3, and the release film RFL is removed. The release film RFL is completely removed, such that the cover layer DCL and the sealing dam structure DAR may remain in the display panel 100. Because the resin layer DCR is cured in a state in which the release film RFL is attached onto the resin layer DCR, the resin layer DCR may be cured in a state in which it completely fills the space formed by the sealing dam structure DAR, such that the upper surface of the resin layer DCR may be planarized. In addition, because a space where the cover layer DCL is disposed may be uniformly controlled by forming the plurality of sealing dams DAR1, DAR2, and DAR3, dispersion of the thickness of the cover layer DCL and appearance quality between the respective fabricating processes may be improved. Because the resin layer DCR may completely fill the space formed by the sealing dam structure DAR while spreading, both of a portion where the cover layer DCL and the sealing dam structure DAR are in contact with each other and the space between the preliminary display panel PAL and the sealing dam structure DAR may be filled with the cover layer DCL. The cover layer DCL disposed at the uppermost layer of the display panel 100 may have a smooth upper surface, and a space between the sealing dam structure DAR and the cover layer DCL may not be formed.

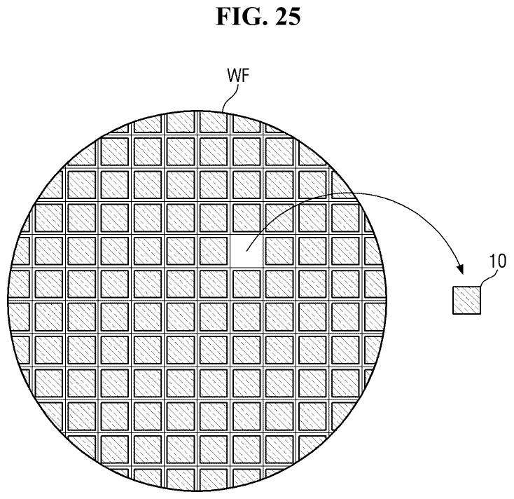

Subsequently, referring to FIG. 25, the display panel 100 is formed by dividing the wafer substrate WF, and the display device 10 is fabricated by attaching the circuit board 300 to the display panel 100. The wafer substrate WF may be divided for each unit area where one preliminary display panel PAL and the cover layer DCL are formed. The fabricating processes of the display device 10 may be performed so that several display panels 100 may be fabricated on one wafer substrate WF. Accordingly, a fabricating yield of the display device 10 may be excellent.

In addition, in a process of dividing the wafer substrate WF, the cover layer DCL is formed to correspond to each of the preliminary display panels PAL, and accordingly, there is no process of dividing a separate cover member covering the preliminary display panels PAL. Therefore, there is an advantage that the display panel 100 is free from breakage or damage.

Hereinafter, various embodiments of the display device 10 will be described with reference to other drawings.

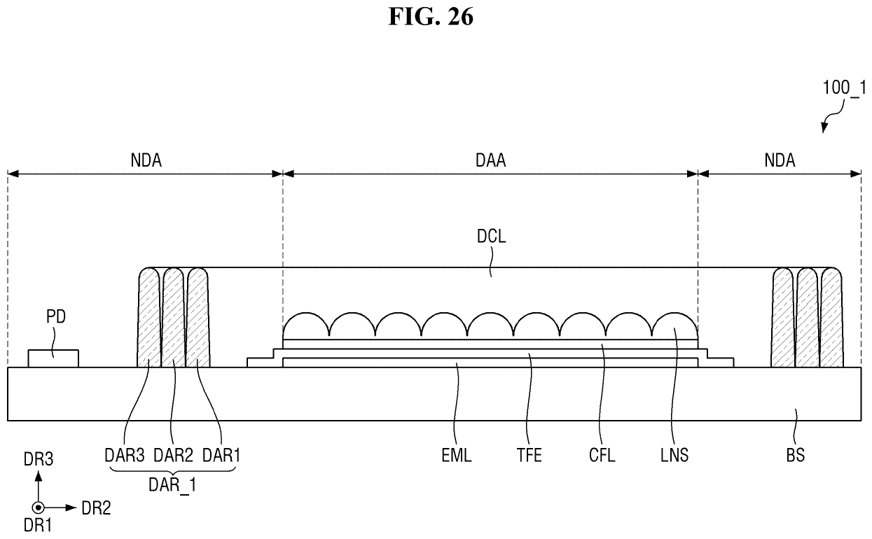

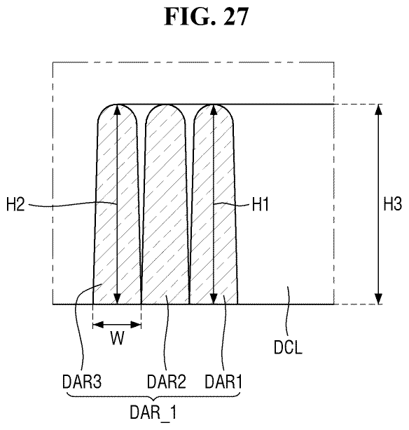

FIG. 26 is a schematic cross-sectional view of a display panel of a display device according to one or more embodiments taken along the second direction (e.g., DR2). FIG. 27 is a cross-sectional view illustrating a sealing dam structure of the display device of FIG. 26 in more detail.

Referring to FIGS. 26 and 27, in a display device 10 according to one or more embodiments, a plurality of sealing dams DAR1, DAR2, and DAR3 of a sealing dam structure DAR_1 may have the same material and height, and a cover layer DCL may be disposed to fill an area surrounded by the outermost sealing dam. Heights H1 and H2 of a first sealing dam DAR1, a second sealing dam DAR2, and a third sealing dam DAR3 may be the same as each other, and a maximum thickness H3 of the cover layer DCL may also be the same as the heights of the sealing dams DAR1, DAR2, and DAR3. The cover layer DCL may fill a space between the first sealing dam DAR1 and the second sealing dam DAR2, and may also fill a space between the second sealing dam DAR2 and the third sealing dam DAR3.

The sealing dam structure DAR_1 may be made of sealing dam resins DRS1, DRS2, and DRS3 in fabricating processes of the display device 10 and then may be completely cured together with the resin layer DCR. In one or more embodiments of FIGS. 26 and 27, in a process of forming the sealing dams DAR1, DAR2, and DAR3 of the sealing dam structure DAR, the stamping process may be performed after the sealing dam resins DRS1, DRS2, and DRS3 including the fast cured-type polymer resins are formed. Accordingly, the sealing dam resins DRS1, DRS2, and DRS3 may have different heights in the state in which they are completely cured, the height of only the third sealing dam resin DRS3 may be slightly lowered in the stamping process to become the same as the height of the second sealing dam resin DRS2.

On the other hand, in the sealing dams DAR1, DAR2, and DAR3 of the sealing dam structure DAR_1 of FIGS. 26 and 27, the sealing dam resins DRS1, DRS2, and DRS3 in an uncured state may be formed at the same height. In the stamping process performed subsequently, heights of the sealing dam resins DRS1, DRS2, and DRS3 in the uncured state may each be slightly lowered, and the resin layer DCR may spread while filling spaces between different sealing dam resins DRS1, DRS2, and DRS3. The sealing dams DAR1, DAR2, and DAR3 formed by completely curing the sealing dam resins DRS1, DRS2, and DRS3 after the stamping process may have the same height, and the cover layer DCL may also fill the space between the third sealing dam DAR3 and the second sealing dam DAR2.

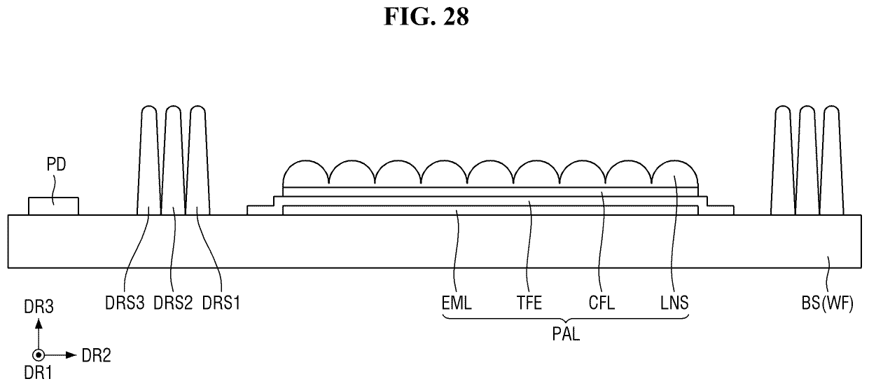

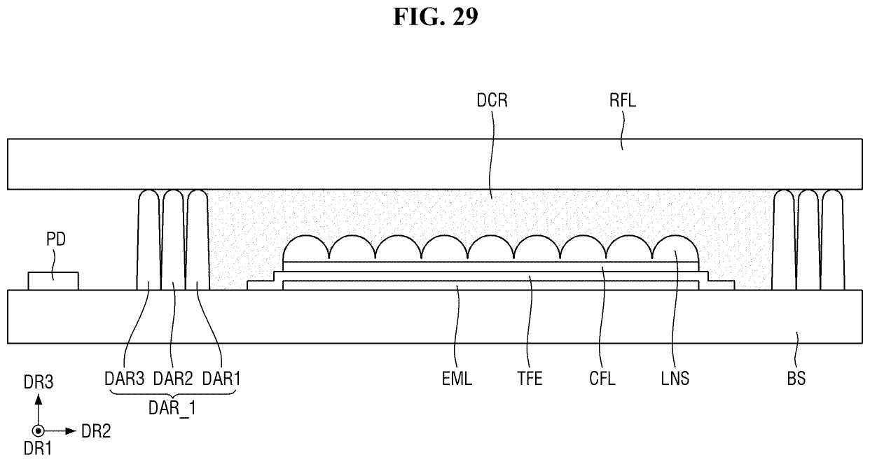

FIGS. 28 and 29 are cross-sectional views illustrating some of fabricating processes of the display device of FIG. 26.

Referring to FIGS. 28 and 29, the preliminary display panel PAL is formed on the wafer substrate WF (or the base substrate BS), and a plurality of sealing dam resins DRS1, DRS2, and DRS3 are formed to be around (e.g., to surround) the preliminary display panel PAL. Unlike an embodiment of FIG. 20, the sealing dam resins DRS1, DRS2, and DRS3 may include uncured-type polymer resins. Materials of the sealing dam resins DRS1, DRS2, and DRS3 are changed, and accordingly, heights of the sealing dam resins DRS1, DRS2, and DRS3 may all be the same as each other. In a stamping process of FIG. 29, heights of the sealing dam resins DRS1, DRS2, and DRS3 may each be lowered to a suitable level (e.g., a predetermined level), and in this process, the resin layer DCR may spread while filling a space between the third sealing dam resin DRS3 and the second sealing dam resin DRS2. In addition, the first to third sealing dam resins DRS1, DRS2, and DRS3 may support the release film RFL while their heights are concurrently (e.g., simultaneously) lowered uniformly. A thickness of the resin layer DCR may be the same as the height of the first to third sealing dam resins DRS1, DRS2, and DRS3, and a thickness of the cover layer DCL may be controlled through the height of the first to third sealing dam resins DRS1, DRS2, and DRS3.

Subsequently, in one or more embodiments, the resin layer DCR and the sealing dam resins DRS1, DRS2, and DRS3 are completely cured through UV irradiation or heat treatment to form the cover layer DCL and the sealing dam structure DAR_1.

In the display device 10 according to the present embodiment, the plurality of sealing dams DAR1, DAR2, and DAR3 may have the same height, and may be made of the sealing dam resins DRS1, DRS2, and DRS3 including the uncured-type polymer resins during the fabricating processes. Accordingly, in the stamping process, the heights of the sealing dam resins DRS1, DRS2, and DRS3 in an uncured state may be lowered, and spread dispersion of the resin layer DCR may be uniformly controlled. In the display device 10, even though the plurality of sealing dams DAR1, DAR2, and DAR3 have the same height, the cover layer DCL may be controlled to fill the spaces between the sealing dams DAR1, DAR2, and DAR3 without going beyond the outermost sealing dam.

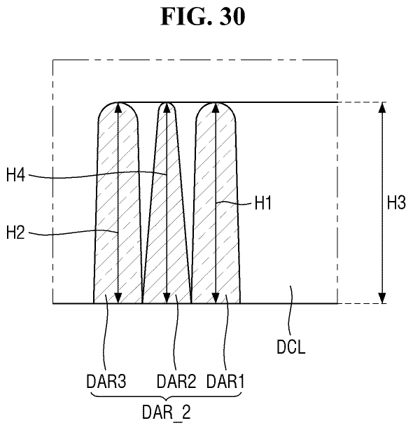

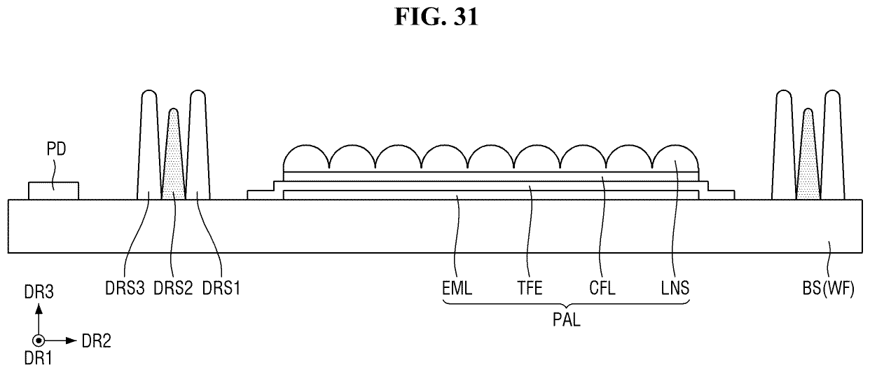

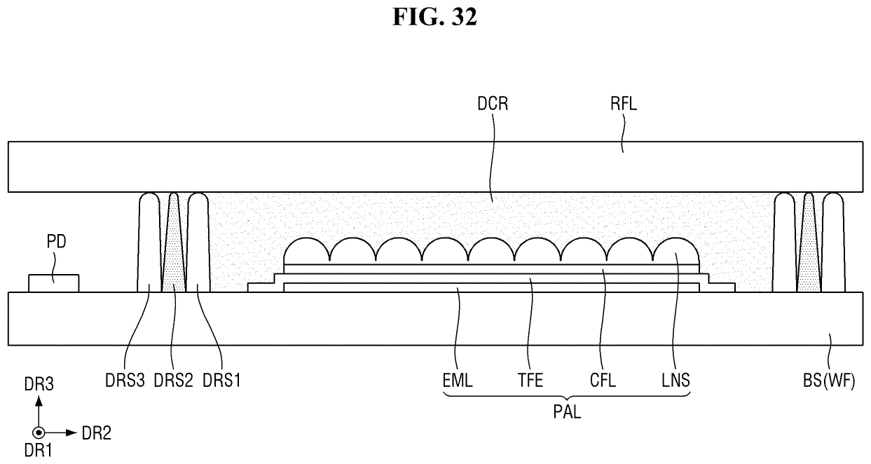

FIG. 30 is a cross-sectional view illustrating a sealing dam structure of a display device according to still another embodiment in more detail. FIGS. 31 and 32 are cross-sectional views illustrating some of fabricating processes of the display device including the sealing dam structure of FIG. 30.

Referring to FIGS. 30-32, in a display device 10 according to one or more embodiments, a plurality of sealing dams DAR1, DAR2, and DAR3 of a sealing dam structure DAR_2 may have the same height, but an intermediate sealing dam may include a different material from the innermost sealing dam and the outermost sealing dam. The first sealing dam DAR1 and the third sealing dam DAR3 may be formed by curing uncured-type sealing dam resins, and heights H1 and H2 of the first sealing dam DAR1 and the third sealing dam DAR3 may be the same as each other. The second sealing dam DAR2 may be formed by curing a fast cured-type sealing dam resin, and after the fast cured-type sealing dam resin is completely cured, a height H4 of the second sealing dam DAR2 may be the same as the heights H1 and H2 of the first sealing dam DAR1 and the third sealing dam DAR3. The cover layer DCL may be disposed to also fill a space between the second sealing dam DAR2 and the third sealing dam DAR3, and a maximum thickness H3 of the cover layer DCL may be the same as the heights of the sealing dams DAR1, DAR2, and DAR3.

In fabricating processes of the display device 10, some of a plurality of sealing dam resins DRS1, DRS2, and DRS3 may have different heights and materials. For example, a first sealing dam resin DRS1 and a third sealing dam resin DRS3 may be made of uncured-type polymer resins, and a second sealing dam resin DRS2 may be made of a fast cured-type polymer resin. The first sealing dam resin DRS1 and the third sealing dam resin DRS3 are formed in an uncured state to have greater heights than the second sealing dam resin DRS2 in a cured state.

In a stamping process, the heights of the first sealing dam resin DRS1 and the third sealing dam resin DRS3 may be lowered to become the same as the height of the second sealing dam resin DRS2. The resin layer DCR may spread beyond the first sealing dam resin DRS1 as the height of the first sealing dam resin DRS1 is lowered. In addition, the second sealing dam resin DRS2 also has a relatively low height, and thus, the resin layer DCR may also spread beyond the second sealing dam resin DRS2. The resin layer DCR may fill the space between the third sealing dam resin DRS3 and the second sealing dam resin DRS2.

The release film RFL may be supported by the second sealing dam resin DRS2 in the cured state and the first sealing dam resin DRS1 and third sealing dam resin DRS3 which is in the uncured state and whose heights are lowered to a suitable level (e.g., a predetermined level). A thickness of the resin layer DCR and a thickness of the cover layer DCL may be controlled by the height of the second sealing dam resin DRS2. Subsequently, in one or more embodiments, the resin layer DCR and the sealing dam resins DRS1, DRS2, and DRS3 are completely cured through UV irradiation or heat treatment to form the cover layer DCL and the sealing dam structure DAR_2.

In one or more embodiments, shapes of upper ends of the first sealing dam DAR1 and the third sealing dam DAR3 whose heights were lowered in the stamping process from among the sealing dams DAR1, DAR2, and DAR3 may be different from that of the second sealing dam DAR2. The second sealing dam DAR2 may be made of the sealing dam resin in the cured state and may be then in a state where it is hardly transformed due to the release film RFL. On the other hand, the first sealing dam DAR1 and the third sealing dam DAR3 may be made of the sealing dam resins in the uncured state and the upper ends of the first sealing dam DAR1 and the third sealing dam DAR3 may then be pressed by the release film RFL, such that the first sealing dam DAR1 and the third sealing dam DAR3 may be partially transformed. For example, the upper ends of the first sealing dam DAR1 and the third sealing dam DAR3 may have a more rounded shape than the upper end of the second sealing dam DAR2. However, the present disclosure is not limited thereto, and shapes of the upper ends of the first to third sealing dams DAR1, DAR2, and DAR3 may also be substantially the same s each other.

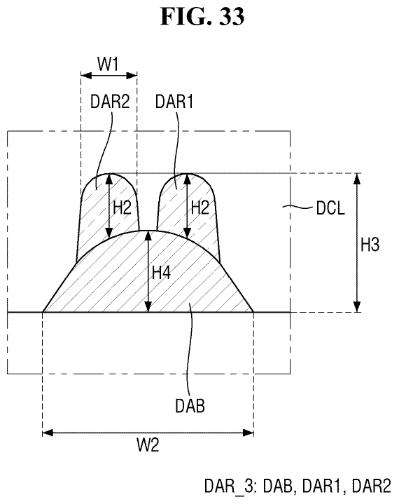

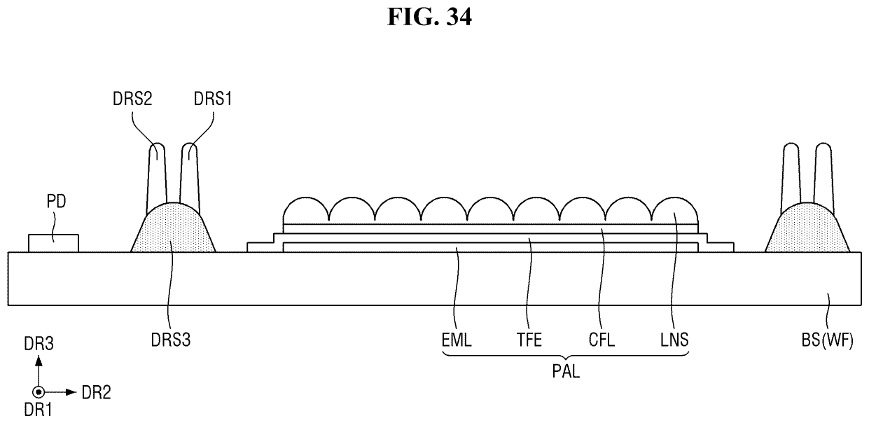

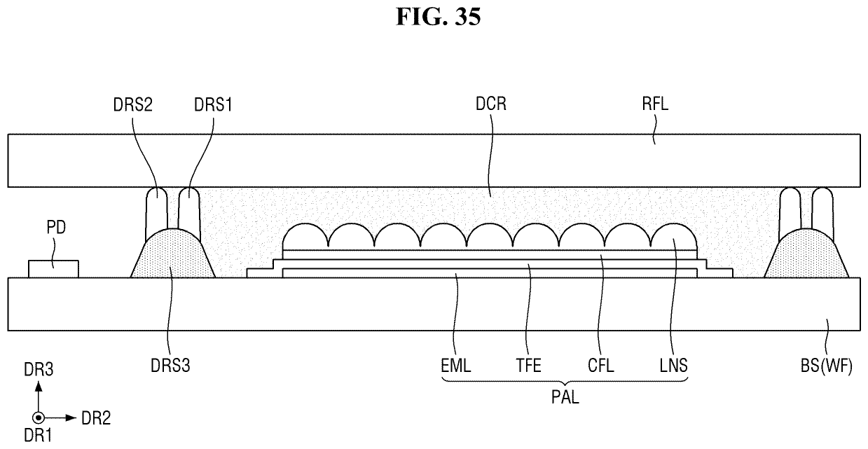

FIG. 33 is a cross-sectional view illustrating a sealing dam structure of a display device according to still another embodiment in more detail. FIGS. 34 and 35 are cross-sectional views illustrating some of fabricating processes of the display device including the sealing dam structure of FIG. 33.

Referring to FIGS. 33-35, in a display device 10 according to one or more embodiments, a plurality of sealing dam structures DAR_3 may include two sealing dams DAR1 and DAR2 spaced (or spaced apart) from each other and a base sealing dam DAB disposed below the two sealing dams DAR1 and DAR2. A height H4 of the base sealing dam DAB may be greater than a height H2 of a first sealing dam DAR1 and a second sealing dam DAR2 disposed on the base sealing dam DAB. A width W2 of the base sealing dam DAB may be greater than a width W1 of each of the first sealing dam DAR1 and the second sealing dam DAR2. In addition, the width W2 of the base sealing dam DAB may be greater than the sum (W1*2) of the widths of the first sealing dam DAR1 and the second sealing dam DAR2. The cover layer DCL may fill a space between the first sealing dam DAR1 and the second sealing dam DAR2, and a maximum thickness H3 of the cover layer DCL may be the same as a height measured from a lower surface of the base sealing dam DAB to an upper surface of the first sealing dam DAR1.

In one or more embodiments, a base sealing dam DAB may be made of a fast cured-type sealing dam resin DRS3, and the first sealing dam DAR1 and the second sealing dam DAR2 may be made of uncured-type sealing dam resins DRS1 and DRS2. The resin layer DCR may fill a space between the first sealing dam resin DRS1 and the second sealing dam resin DRS2 while heights of the uncured-type first sealing dam resin DRS1 and second sealing dam resin DRS2 are partially lowered in a stamping process. On the other hand, the fast cured-type third sealing dam resin DRS3 is hardly transformed in the stamping process, and may support the release film RFL together with the first sealing dam resin DRS1 and the second sealing dam resin DRS2. In the display device 10, a thickness of the resin layer DCR may be controlled to some degree through the fast cured-type third sealing dam resin DRS3 disposed below the first sealing dam resin DRS1 and the second sealing dam resin DRS2, and spread dispersion of the resin layer DCR may be uniformly controlled through the uncured-type first sealing dam resin DRS1 and second sealing dam resin DRS2 disposed on the third sealing dam resin DRS3.

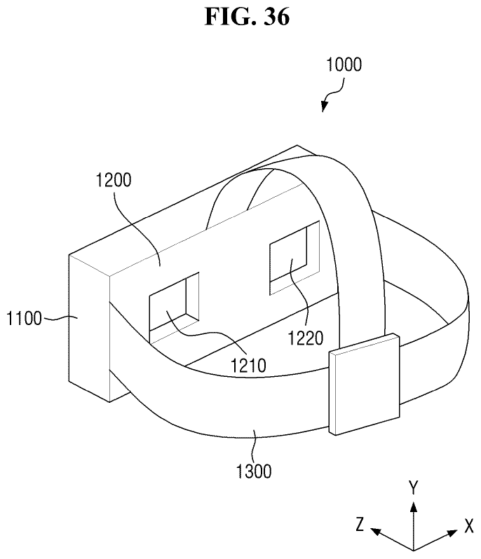

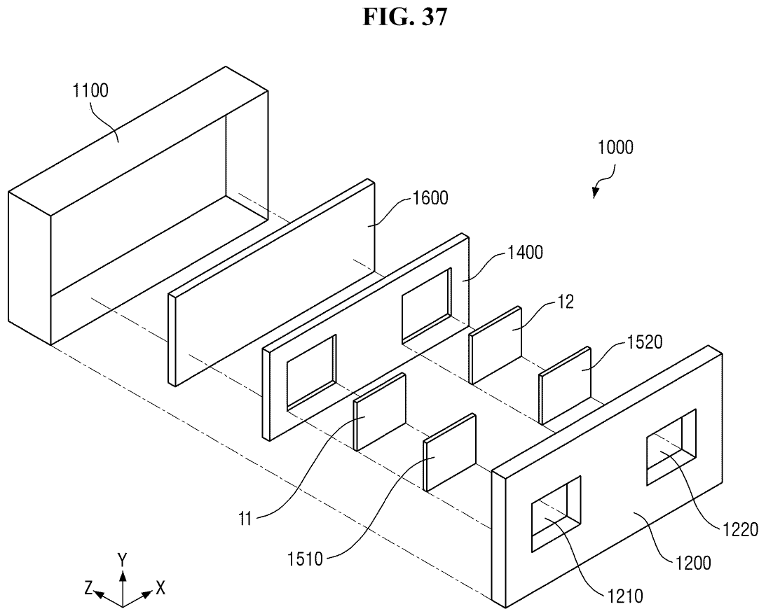

FIG. 36 is a perspective view illustrating a head mounted display device according to one or more embodiments. FIG. 37 is an exploded perspective view illustrating an example of the head mounted display device of FIG. 36.

Referring to FIGS. 36 and 37, a head mounted display device 1000 according to one or more embodiments includes a first display device 11, a second display device 12, a display device housing portion 1100, a housing portion cover 1200, a first eyepiece 1210, a second eyepiece 1220, a head mounted band 1300, a middle frame 1400, a first optical member 1510, a second optical member 1520, a control circuit board 1600, and a connector.

The first display device 11 provides an image to a user's left eye, and the second display device 12 provides an image to a user's right eye. Each of the first display device 11 and the second display device 12 is substantially the same as the display device 10 described with reference to FIG. 1, and a description of the first display device 11 and the second display device 12 is thus omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600 and disposed between the second display device 12 and the control circuit board 1600. The middle frame 1400 serves to support and fix the first display device 11, the second display device 12, and the control circuit board 1600.

The control circuit board 1600 may be disposed between the middle frame 1400 and the display device housing portion 1100. The control circuit board 1600 may be connected to the first display device 11 and the second display device 12 through the connector. The control circuit board 1600 may convert an image source input from the outside into digital video data DATA, and transmit the digital video data DATA to the first display device 11 and the second display device 12 through the connector.

The control circuit board 1600 may transmit digital video data DATA corresponding to a left eye image that is suitable (e.g., optimized) for the user's left eye to the first display device 11 and transmit digital video data DATA corresponding to a right eye image that is suitable (e.g., optimized) for the user's right eye to the second display device 12. Alternatively, the control circuit board 1600 may transmit the same digital video data DATA to the first display device 11 and the second display device 12.

The display device housing portion 1100 serves to house the first display device 11, the second display device 12, the middle frame 1400, the first optical member 1510, the second optical member 1520, the control circuit board 1600, and the connector. The housing portion cover 1200 is disposed to cover opened one surface of the display device housing portion 1100. The housing portion cover 1200 may include the first eyepiece 1210 on which the user's left eye is disposed and the second eyepiece 1220 on which the user's right eye is disposed. It has been illustrated in FIGS. 36 and 37 that the first eyepiece 1210 and the second eyepiece 1220 are separately disposed, but the present disclosure is not limited thereto. The first eyepiece 1210 and the second eyepiece 1220 may be merged as one eyepiece.

The first eyepiece 1210 may be aligned with the first display device 11 and the first optical member 1510, and the second eyepiece 1220 may be aligned with the second display device 12 and the second optical member 1520. Accordingly, a user may view an image of the first display device 11 magnified as a virtual image by the first optical member 1510 through the first eyepiece 1210, and may view an image of the second display device 12 magnified as a virtual image by the second optical member 1520 through the second eyepiece 1220.

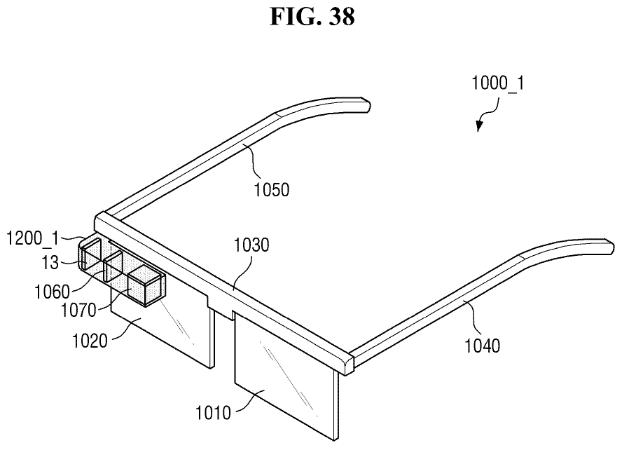

The head mounted band 1300 serves to fix the display device housing portion 1100 to a user's head so that the first eyepiece 1210 and the second eyepiece 1220 of the housing portion cover 1200 may be maintained in a state in which they are disposed on the user's left eye and right eye, respectively. When the display device housing portion 1200 is implemented to have a light weight and a small size, the head mounted display device 1000 may include an eyeglass frame as illustrated in FIG. 38 instead of the head mounted band 1300.

In addition, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, and/or a Bluetooth module.

FIG. 38 is a perspective view illustrating a head mounted display device according to one or more embodiments.

Referring to FIG. 38, a head mounted display device 1000_1 according to one or more embodiments may be a glasses-type display device in which a display device housing portion 1200_1 is implemented to have a light weight and a small size. The head mounted display device 1000_1 according to one or more embodiments may include a display device 13, a left eye lens 1010, a right eye lens 1020, a support frame 1030, glasses frame legs 1040 and 1050, an optical member 1060, an optical path conversion member 1070, and a display device housing portion 1200_1.

The display device housing portion 1200_1 may include the display device 13, the optical member 1060, and the optical path conversion member 1070. An image displayed on the display device 13 may be magnified by the optical member 1060, converted in an optical path by the optical path conversion member 1070, and provided to a user's right eye through the right eye lens 1020. For this reason, a user may view an augmented reality image in which a virtual image displayed on the display device 13 through his/her right eye and a real image seen through the right eye lens 1020 are combined with each other.

It has been illustrated in FIG. 38 that the display device housing portion 1200_1 is disposed at a right end of the support frame 1030, but the present disclosure is not limited thereto. For example, the display device housing portion 1200_1 may be disposed at a left end of the support frame 1030, and in this case, an image of the display device 13 may be provided to a user's left eye. Alternatively, the display device housing portions 1200_1 may be disposed at both the left and right ends of the support frame 1030, and in this case, the user may view an image displayed on the display device 13 through both his/her left and right eyes.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate including a display area and a non-display area around the display area, a plurality of transistors being located on the substrate;
a light emitting element layer on the substrate and comprising a plurality of light emitting elements in the display area;
an encapsulation layer on the light emitting element layer;
a color filter layer on the encapsulation layer and comprising a plurality of color filters overlapping the light emitting elements, respectively;
a lens array layer on the color filter layer and comprising a plurality of lenses in the display area;
a sealing dam structure in the non-display area and comprising a plurality of sealing dams surrounding the display area; and
a cover layer on the lens array layer and located in an area surrounded by the sealing dam structure,
the plurality of sealing dams comprising a first sealing dam adjacent to the display area and a second sealing dam around the first sealing dam, and at least a portion of the cover layer being between the first sealing dam and the second sealing dam.

2. The display device of claim 1, wherein the sealing dam structure further comprises a third sealing dam around the second sealing dam, and the cover layer does not go beyond the third sealing dam.

3. The display device of claim 2, wherein a height of the first sealing dam is smaller than heights of the second sealing dam and the third sealing dam, and wherein the heights of the second sealing dam and the third sealing dam are a same.

4. The display device of claim 3, wherein the cover layer covers the first sealing dam, and wherein the cover layer is not located between the second sealing dam and the third sealing dam.

5. The display device of claim 3, wherein a maximum thickness of the cover layer is the same as the heights of the second sealing dam and the third sealing dam.

6. The display device of claim 2, wherein heights of the first sealing dam, the second sealing dam, and the third sealing dam are the same, and
wherein at least a portion of the cover layer is located between the second sealing dam and the third sealing dam.

7. The display device of claim 6, wherein the first sealing dam, the second sealing dam, and the third sealing dam comprise a same material.

8. The display device of claim 6, wherein the first sealing dam and the third sealing dam comprise a same material, and
wherein the second sealing dam comprises a different material from the first sealing dam and the third sealing dam.

9. The display device of claim 1, wherein the sealing dam structure further comprises a base sealing dam below the first sealing dam and the second sealing dam, and
wherein a thickness of the base sealing dam is greater than a thickness of each of the first sealing dam and the second sealing dam.

10. The display device of claim 9, wherein the first sealing dam and the second sealing dam comprise a same material, and
wherein the base sealing dam comprises a different material from the first sealing dam and the second sealing dam.

11. The display device of claim 1, wherein a width of each of the first sealing dam and the second sealing dam is in a range of 500 μm to 600 μm.

12. The display device of claim 1, wherein the first sealing dam and the second sealing dam comprise a polymer resin, and
wherein the polymer resin has a viscosity in a range of 50,000 cP to 300,000 cP and has a thixotropic index in a range of 4 to 6.

13. The display device of claim 1, further comprising a plurality of pads disposed in the non-display area of the substrate,
wherein the sealing dam structure does not surround the pads, and the cover layer does not overlap the pads.

14. A method of fabricating a display device, comprising:
preparing a substrate on which a plurality of transistors is located and in which a plurality of unit areas are defined and forming a light emitting element layer, an encapsulation layer, a color filter layer, and a lens array layer in each of the unit areas of the substrate, the light emitting element layer comprising a plurality of light emitting elements, the encapsulation layer being on the light emitting element layer, the color filter layer being on the encapsulation layer, and the lens array layer being on the color filter layer;
forming a plurality of sealing dam resins around a display area where the light emitting element layer is located and applying a resin layer onto the lens array layer in an area surrounded by the sealing dam resins;
planarizing an upper surface of the resin layer by disposing a release film on the resin layer and the sealing dam resins; and
forming a cover layer and a plurality of sealing dams by curing the resin layer and the sealing dam resins and forming a plurality of display panels by dividing the substrate for each of the unit areas, the cover layer around the light emitting element layer, the encapsulation layer, the color filter layer, and the lens array layer, and the plurality of sealing dams around the display area,
at least a portion of the cover layer being between the plurality of sealing dams.

15. The method of fabricating the display device of claim 14, wherein the plurality of sealing dam resins comprise a first sealing dam resin, a second sealing dam resin, and a third sealing dam resin, and
wherein the first sealing dam resin has a height smaller than heights of the second sealing dam resin and the third sealing dam resin, and is most adjacent to the display area from among the plurality of sealing dam resins.

16. The method of fabricating the display device of claim 15, wherein in the planarizing of the upper surface of the resin layer, the heights of the second sealing dam resin and the third sealing dam resin become the same.

17. The method of fabricating the display device of claim 14, wherein heights of the plurality of sealing dam resins are the same, and
wherein at least a portion of the cover layer is between an outermost sealing dam of the plurality of sealing dams and a sealing dam located inside the outermost sealing dam.

18. The method of fabricating the display device of claim 14, wherein the plurality of sealing dam resins comprise a first sealing dam resin, a second sealing dam resin around the first sealing dam resin and having a smaller height than the first sealing dam resin, and a third sealing dam resin around the second sealing dam resin and having a same height as the first sealing dam resin, and
wherein each of the first sealing dam resin and the third sealing dam resin comprises an uncured-type polymer resin, and the second sealing dam resin comprises a fast cured-type polymer resin.

19. The method of fabricating the display device of claim 14, wherein the plurality of sealing dam resins comprise a first sealing dam resin, a second sealing dam resin around the first sealing dam resin, and a third sealing dam resin located below the first sealing dam resin and the second sealing dam resin, and
wherein a width of the third sealing dam resin is greater than a width of each of the first sealing dam resin and the second sealing dam resin.

20. A head mounted display device comprising:
a frame corresponding to left and right eyes of a user;
a plurality of display devices in the frame; and
eyepieces on the plurality of display devices, respectively,
wherein the display device comprises:
a substrate including a display area and a non-display area around the display area, a plurality of transistors being on the substrate;
a light emitting element layer on the substrate and comprising a plurality of light emitting elements in the display area;
an encapsulation layer on the light emitting element layer;
a color filter layer on the encapsulation layer and comprising a plurality of color filters overlapping the light emitting elements, respectively;
a lens array layer on the color filter layer and comprising a plurality of lenses in the display area;
a sealing dam structure in the non-display area and comprising a plurality of sealing dams around the display area; and
a cover layer on the lens array layer and located in an area surrounded by the sealing dam structure,
the plurality of sealing dams comprising an innermost sealing dam adjacent to the display area, an outermost sealing dam around the innermost sealing dam, and
at least one intermediate dam between the innermost sealing dam and the outermost sealing dam, and
at least a portion of the cover layer being between the outermost sealing dam and the innermost sealing dam, and not being outside the outermost sealing dam.
